(19) United States
(12) Patent Application Publication
(10) Pub. No.: US 2024/0153923 A1
(43) Pub. Date: May 9, 2024

(54) DISPLAY DEVICE AND METHOD OF MANUFACTURING THE SAME

(71) Applicant: Samsung Display Co., Ltd., Yongin-si (KR)

(72) Inventors: Veidhes BASRUR, Yongin-si (KR); Guang Hai JIN, Yongin-si (KR); Ki Nyeng KANG, Yongin-si (KR)

(73) Assignee: Samsung Display Co., Ltd., Yongin-si (KR)

(21) Appl. No.: 18/328,894

(22) Filed: Jun. 5, 2023

(30) Foreign Application Priority Data
Nov. 4, 2022 (KR) 10-2022-0146486

(51) Int. Cl. H01L 25/075; H01L 25/16; H01L 33/38; H01L 33/62

(52) U.S. Cl. CPC H01L 25/0753; H01L 25/167; H01L 33/38; H01L 33/62; H01L 2933/0016; H01L 2933/0066

(57) ABSTRACT

A display device includes a first pixel including a first emission area; a second pixel including a second emission area spaced apart from the first emission area in a second direction; and a bank defining a non-emission area between the first emission area and the second emission area. Each of the first pixel and the second pixel includes at least one dummy electrode spaced apart from each other in a first direction intersecting the second direction and extending in the second direction; light emitting elements disposed between the at least one dummy electrode in an emission area; a first pixel electrode electrically connected to a first driving power source and first ends of the light emitting elements; and a second pixel electrode electrically connected to a second driving power source and second ends of the light emitting elements.

### CROSS-REFERENCE TO RELATED APPLICATION

The application claims priority to and the benefit of Korean Patent Application No. 10-2022-0146486, filed in the Korean Intellectual Property Office (KIPO) on Nov. 4, 2022, which is incorporated herein by reference for all purposes as if fully set forth herein.

### BACKGROUND

### 1. Technical Field

The disclosure relates to a display device and a method of manufacturing the same.

### 2. Description of the Related Art

In recent years, as interest in information displays increases, research and development on display devices are continuously being made.

### SUMMARY

An objective of the disclosure is to provide a display device capable of improving light emitting efficiency by repairing a light emitting defect of a light emitting element (or pixel) due to a defect in a pixel circuit connected to the light emitting element, and a method of manufacturing the same.

Objectives of the disclosure are not limited to the above-mentioned object, and other technical objects not mentioned will be clearly understood by those skilled in the art from the following description.

A display device according to embodiments of the disclosure may include a first pixel including a first emission area; a second pixel including a second emission area spaced apart from the first emission area in a second direction; and a bank defining a non-emission area between the first emission area and the second emission area. Each of the first pixel and the second pixel may include at least one dummy electrode spaced apart from each other in a first direction intersecting the second direction and extending in the second direction; light emitting elements disposed between the at least one dummy electrode in an emission area; a first pixel electrode electrically connected to a first driving power source and first ends of the light emitting elements; and a second pixel electrode electrically connected to a second driving power source and second ends of the light emitting elements. The first pixel electrode of the first pixel may extend from the first emission area to the non-emission area, and the first pixel electrode of the first pixel may be electrically connected to one of the at least one dummy electrode of the first pixel. The first pixel electrode of the second pixel may be electrically connected to the first driving power source, and the first pixel electrode of the second pixel may be electrically connected to the at least one dummy electrode.

According to an embodiment, the first pixel electrode of the first pixel may be electrically connected to the first driving power source through the first pixel electrode of the second pixel and the at least one dummy electrode.

According to an embodiment, the at least one dummy electrode of the second pixel may be spaced apart from the at least one dummy electrode of the first pixel in the second direction in the non-emission area, and the at least one dummy electrode of the second pixel may not be electrically connected to the at least one dummy electrode of the first pixel.

According to an embodiment, the second pixel electrode of the second pixel may extend from the second emission area to the non-emission area, and the second pixel electrode of the second pixel may be electrically connected to the at least one dummy electrode through a second contact hole.

According to an embodiment, the at least one dummy electrode of the first pixel may further include a first dummy electrode overlapping the first pixel electrode of the first pixel in a plan view; and a third dummy electrode spaced apart from the first dummy electrode in the first direction and overlapping the second pixel electrode of the first pixel in a plan view.

According to an embodiment, the at least one dummy electrode may be disposed between the first dummy electrode and the third dummy electrode in a plan view.

According to an embodiment, the at least one dummy electrode may be disposed to be farther spaced apart from the third dummy electrode than the first dummy electrode in a plan view.

According to an embodiment, the first pixel electrode of the first pixel may include a first partial electrode overlapping the first dummy electrode in a plan view, and a second partial electrode protruding from the first partial electrode in the first direction and overlapping at least a portion of the at least one dummy electrode in a plan view. The second partial electrode may be electrically connected to the at least one dummy electrode through a first contact hole.

According to an embodiment, the display device may further include an isolated electrode spaced apart from the first pixel electrode of the first pixel in the second direction in the non-emission area. The isolated electrode may be electrically connected to the first dummy electrode through a third contact hole.

A display device according to embodiments of the present invention may include a first pixel including a first emission area; a second pixel including a second emission area spaced apart from the first emission area in a second direction; and a bank defining a non-emission area between the first emission area and the second emission area. Each of the first pixel and the second pixel may include at least one dummy electrode spaced apart from each other in a first direction intersecting the second direction and extending in the second direction; light emitting elements disposed between the at least one dummy electrode in an emission area; a first pixel electrode electrically connected to a first driving power source and first ends of the light emitting elements; and a second pixel electrode electrically connected to a second driving power source and second ends of the light emitting elements. The first pixel electrode of the first pixel may extend from the first emission area to the non-emission area, and the first pixel electrode of the first pixel may be electrically connected to one of the at least one dummy electrode of the second pixel. The first pixel electrode of the second pixel may be electrically connected to the first driving power source, and the first pixel electrode of the second pixel may be electrically connected to the at least one dummy electrode.

According to an embodiment, the at least one dummy electrode of the second pixel may be spaced apart from the at least one dummy electrode of the first pixel in the second direction in the non-emission area, and the at least one dummy electrode of the second pixel may not be electrically connected to the at least one dummy electrode of the first pixel.

According to an embodiment, the at least one dummy electrode of the second pixel may include a first dummy electrode, a second dummy electrode, a third dummy electrode, and a fourth dummy electrode sequentially disposed in the first direction, and the at least one dummy electrode may be the first dummy electrode.

According to an embodiment, the at least one dummy electrode of the first pixel may include a first dummy electrode, a second dummy electrode, a third dummy electrode, and a fourth dummy electrode sequentially disposed in the first direction, and may include an isolated electrode overlapping the first dummy electrode in the non-emission area in a plan view and at least partially surrounded by the first pixel electrode of the first pixel.

According to an embodiment, the first pixel electrode of the first pixel may include a first portion overlapping the first dummy electrode in a plan view; and a bent portion extending from the first portion and overlapping at least a portion of the at least one dummy electrode in a plan view.

According to an embodiment, the bent portion may include a second partial electrode protruding from the first portion in the second direction and overlapping the second dummy electrode in a plan view, and a third partial electrode overlapping at least a portion of the at least one dummy electrode which is one of second dummy electrodes, in a plan view.

According to an embodiment, the third partial electrode may be electrically connected to the at least one dummy electrode through a first contact hole.

A method of manufacturing a display device according to embodiments of the present invention may include disposing a pixel circuit layer on a substrate; forming first to fourth alignment electrodes spaced apart from each other in a first direction on the pixel circuit layer; forming a bank defining a first emission area of a first pixel, a second emission area of a second pixel disposed spaced apart from the first emission area in a second direction intersecting the first direction, and a non-emission area between the first emission area and the second emission area on the first to fourth alignment electrodes; providing light emitting elements to each of the first emission area and the second emission area; disposing a first pixel electrode electrically connected to one end of the light emitting elements and a second pixel electrode electrically connected to another end of the light emitting elements; electrically separating the first to fourth alignment electrodes into at least one dummy electrode overlapping the first emission area in a plan view and at least one dummy electrode overlapping the second emission area in a plan view by removing portions of each of the first to fourth alignment electrodes in the non-emission area; inspecting whether the first pixel and the second pixel are defective by using a mother substrate inspection device; separating an electrical connection between the first pixel electrode of the first pixel and the pixel circuit layer in case that the first pixel is in a defective state based on an inspection result; electrically connecting the first pixel electrode disposed in the non-emission area and one of the at least one dummy electrode of the first pixel; and electrically connecting the at least one dummy electrode to the first pixel electrode of the second pixel.

According to an embodiment, in the separating of the electrical connection between the first pixel electrode of the first pixel and the pixel circuit layer, the first pixel electrode may be separated into an isolated electrode electrically connected to the pixel circuit layer and a partial electrode space apart from the isolated electrode and extending from the first emission area to the non-emission area by radiating a laser to the first pixel electrode in the non-emission area to remove a portion of the first pixel electrode of the first pixel.

According to an embodiment, a portion of the partial electrode protruding in the first direction may be electrically connected to the at least one dummy electrode through a first contact hole, and a portion of the first pixel electrode of the second pixel extending from the second emission area to the non-emission area may be electrically connected to the at least one dummy electrode through a second contact hole.

According to an embodiment, the disposing of the first pixel electrode of the first pixel and the second pixel may include forming the portion of the partial electrode and the portion of the first pixel electrode of the second pixel by using at least one of conductive ink and chemical vapor deposition (CVD).

### BRIEF DESCRIPTION OF THE DRAWINGS

The accompanying drawings, which are included to provide a further understanding of the disclosure, and are incorporated in and constitute a part of this specification, illustrate embodiments of the disclosure, and, together with the description, serve to explain principles of the disclosure.

FIG. 1 is a schematic perspective view schematically illustrating a light emitting element according to embodiments of the disclosure.

FIG. 2 is a schematic cross-sectional view illustrating an example of the light emitting element of FIG. 1.

FIG. 3 is a schematic plan view schematically illustrating a display device according to embodiments of the disclosure.

FIG. 4 is a schematic diagram of an equivalent circuit illustrating an example of a pixel included in the display device of FIG. 3 in case that the pixel is in a normal state.

FIG. 5A is a plan view schematically illustrating an example of the pixel of FIG. 4.

FIGS. 5B and 5C are plan views schematically illustrating other examples of the pixel of FIG. 4.

FIG. 6A is a cross-sectional view schematically illustrating an example of a cross section taken along line A-A′ of FIG. 5A.

FIG. 6B is a cross-sectional view schematically illustrating an example of a cross section taken along line B-B′ of FIG. 5A.

FIG. 6C is a cross-sectional view illustrating first to third pixels included in the display device of FIG. 3.

FIG. 7A is a schematic diagram of an equivalent circuit illustrating an example of the pixel included in the display device of FIG. 3 in case that the pixel is in a defective state.

FIGS. 7B and 7C are schematic diagram of equivalent circuits illustrating an example of the pixel for explaining a repair method for the pixel in a defective state of FIG. 7A.

FIGS. 8 and 9 are schematic plan views illustrating an example of the pixel for explaining the repair method for the pixel in a defective state of FIG. 7A.

FIG. 10 is a cross-sectional view schematically illustrating an example of a cross section taken along line I-I′ of FIG. 8.

FIGS. 11A and 11B are cross-sectional views schematically illustrating an example of a cross section taken along line II-IP of FIG. 9.

FIGS. 12 and 13 are schematic plan views illustrating other examples of the pixel for explaining the repair method for the pixel in a defective state of FIG. 7A.

### DETAILED DESCRIPTION OF THE EMBODIMENTS

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in more detail with reference to the accompanying drawings. The same reference numerals are used for the same elements in the drawings, and duplicate descriptions of the same elements are omitted.

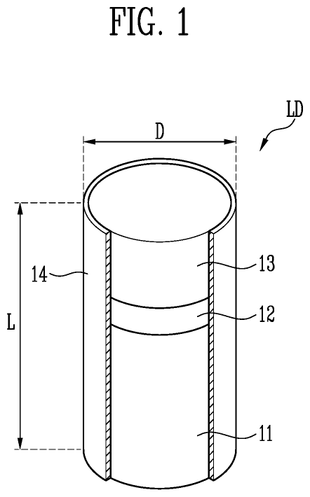

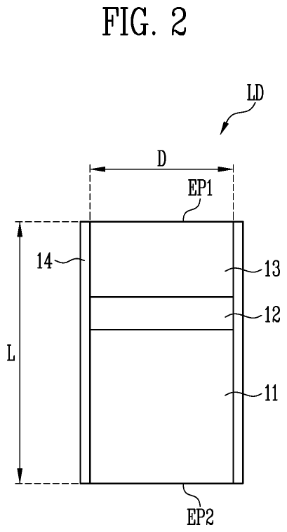

FIG. 1 is a perspective view schematically illustrating a light emitting element according to embodiments of the disclosure. FIG. 2 is a schematic cross-sectional view illustrating an example of the light emitting element of FIG. 1.

Referring to FIGS. 1 and 2, a light emitting element LD may include a first semiconductor layer 11, a second semiconductor layer 13, and an active layer 12 disposed or interposed between the first and second semiconductor layers 11 and 13. For example, the light emitting element LD may be implemented as a light emitting laminate (or laminated pattern) in which the first semiconductor layer 11, the active layer 12, and the second semiconductor layer 13 are sequentially stacked each other.

In an embodiment, the light emitting element LD may be provided in a shape extending in a direction. In case that an extension direction of the light emitting element LD is referred to as a longitudinal direction, the light emitting element LD may include a first end EP1 and a second end EP2 in the longitudinal direction. One of the first semiconductor layer 11 and the second semiconductor layer 13 may be positioned at the first end EP1 of the light emitting element LD. The other of the first semiconductor layer 11 and the second semiconductor layer 13 may be positioned at the second end EP2 of the light emitting element LD.

In an embodiment, the light emitting element LD may be provided in various shapes. As an example, as shown in FIG. 1, the light emitting element LD may have a rod-like shape, a bar-like shape, or a columnar shape that is long in the longitudinal direction (or with an aspect ratio greater than about 1). As another example, the light emitting element LD may have a rod-like shape, a bar-like shape, or a columnar shape that is short in the longitudinal direction (or with an aspect ratio less than about 1). As another example, the light emitting element LD may have a rod-like shape, a bar-like shape, or a columnar shape having an aspect ratio of about 1.

As an example, the light emitting element LD may include a light emitting diode (LED) manufactured in an ultra-small size to have a diameter D and/or a length L of a nano-scale (or nanometer) to a micro-scale (or micrometer).

In an embodiment, in case that the light emitting element LD is long in the longitudinal direction (for example, has an aspect ratio greater than about 1), the diameter D of the light emitting element LD may be about 0.5 μm to about 6 μm, and the length L of the light emitting element LD may be about 1 μm to about 10 μm. However, the diameter D and length L of the light emitting element LD are not limited thereto. The size of the light emitting element LD may be changed to meet requirements (or design conditions) of a lighting device or a self-light emitting display device to which the light emitting element LD is applied.

In an embodiment, the first semiconductor layer 11 may include, for example, at least one n-type semiconductor layer. In the longitudinal direction of the light emitting element LD, the first semiconductor layer 11 may include an upper surface contacting the active layer 12 and a lower surface exposed to the outside. The lower surface of the first semiconductor layer 11 may be an end (or lower end) of the light emitting element LD.

In an embodiment, the active layer 12 may be disposed on the first semiconductor layer 11 and may be formed in a single or multiple quantum well structure. As an example, in case that the active layer 12 is formed in a multiple quantum well structure, the active layer 12 may have a structure in which a barrier layer, a strain reinforcing layer, and a well layer are periodically and repeatedly stacked as a part. Since the strain reinforcing layer has a smaller lattice constant than the barrier layer, strain applied to the well layer, for example, compressive strain, may be further strengthened. However, the structure of the active layer 12 is not limited to the above-described embodiment.

In an embodiment, the active layer 12 may emit light having a wavelength of about 400 nm to about 900 nm, and a double hetero structure may be used. The active layer 12 may include a first surface contacting the first semiconductor layer 11 and a second surface contacting the second semiconductor layer 13.

In an embodiment, the color (or emission color) of the light emitting element LD may be determined according to the wavelength of the light emitted from the active layer 12. The color of the light emitting element LD may determine the color of a corresponding pixel. For example, the light emitting element LD may emit red light, green light, or blue light.

In an embodiment, in case that an electric field of a voltage (e.g., a predetermined or selectable voltage) or higher is applied to ends of the light emitting element LD, the light emitting element LD may emit light while electron-hole pairs are combined in the active layer 12. By controlling the light emission of the light emitting element LD using this principle, the light emitting element LD may be used as a light source (or light emitting source) of various light emitting devices including pixels of a display device.

In an embodiment, the second semiconductor layer 13 may be disposed on the second surface of the active layer 12 and may include a semiconductor layer of a different type from the first semiconductor layer 11. As an example, the second semiconductor layer 13 may include at least one p-type semiconductor layer.

In an embodiment, in the longitudinal direction of the light emitting element LD, the second semiconductor layer 13 may include a lower surface contacting the second surface of the active layer 12 and an upper surface exposed to the outside. The upper surface of the second semiconductor layer 13 may be another end (or upper end) of the light emitting element LD.

In an embodiment, the first semiconductor layer 11 and the second semiconductor layer 13 may have different thicknesses in the longitudinal direction of the light emitting element LD. As an example, the first semiconductor layer 11 may have a relatively greater thickness than the second semiconductor layer 13 in the longitudinal direction of the light emitting element LD. Accordingly, the active layer 12 of the light emitting element LD may be positioned closer to the upper surface of the second semiconductor layer 13 than to the lower surface of the first semiconductor layer 11.

FIGS. 1 and 2 illustrate an embodiment in which each of the first semiconductor layer 11 and the second semiconductor layer 13 is configured as one layer, but the disclosure is not limited thereto. In an example, depending on the material of the active layer 12, each of the first semiconductor layer 11 and the second semiconductor layer 13 may further include one or more layers, for example, a cladding layer and/or a tensile strain barrier reducing (TSBR) layer. The TSBR layer may be a strain relief layer disposed between semiconductor layers having different lattice structures and serving as a buffer to reduce a difference in lattice constant. The TSBR layer may be composed of a p-type semiconductor layer such as p-GaInP, p-AlInP, p-AlGaInP, or the like, but the disclosure is not limited thereto.

In an embodiment, in addition to the above-described first semiconductor layer 11, active layer 12, and second semiconductor layer 13, the light emitting element LD may further include a contact electrode (hereinafter referred to as “first contact electrode”) disposed on the second semiconductor layer 13. According to another embodiment, another contact electrode (hereinafter referred to as “second contact electrode”) disposed on an end of the first semiconductor layer 11 may be further included.

In an embodiment, each of the first and second contact electrodes may be an ohmic contact electrode, but the disclosure is not limited thereto. According to an embodiment, the first and second contact electrodes may be Schottky contact electrodes. The first and second contact electrodes may include a conductive material.

In an embodiment, the light emitting element LD may further include an insulating film 14 (or an insulating thin film). However, according to an embodiment, the insulating film 14 may be omitted or may be provided to cover only portions of the first semiconductor layer 11, the active layer 12, and the second semiconductor layer 13.

In an embodiment, the insulating film 14 may prevent an electrical short circuit that may occur in case that the active layer 12 contacts a conductive material other than the first and second semiconductor layers 11 and 13. The insulating film 14 may minimize surface defects of the light emitting element LD to improve the lifespan and light emitting efficiency of the light emitting element LD. Whether or not the insulating film 14 is provided may not be limited as long as it is possible to prevent the active layer 12 from being short-circuited with an external conductive material.

In an embodiment, the insulating film 14 may surround at least a portion of an outer circumferential surface of the light emitting laminate including the first semiconductor layer 11, the active layer 12, and the second semiconductor layer 13.

In the above-described embodiment, the form in which the insulating film 14 entirely surrounds the outer circumferential surface of each of the first semiconductor layer 11, the active layer 12, and the second semiconductor layer 13 has been described, but the disclosure is limited thereto.

In an embodiment, the insulating film 14 may include a transparent insulating material. For example, the insulating film 14 may include at least one insulating material selected from the group consisting of silicon oxide (SiOx), silicon nitride (SiNx), silicon oxynitride (SiOxNy), aluminum oxide (AlOx), titanium oxide (TiOx), hafnium oxide (HfOx), titanium strontium oxide (SrTiOx), cobalt oxide (CoxOy), magnesium oxide (MgO), zinc oxide (ZnOx), ruthenium oxide (RuOx), nickel oxide (NiO), tungsten oxide (WOx), tantalum oxide (TaOx), gadolinium oxide (GdOx), zirconium oxide (ZrOx), gallium oxide (GaOx), vanadium oxide (VxOy), ZnO:Al, ZnO:B, InxOy:H, niobium oxide (NbxOy), magnesium fluoride (MgFX), aluminum fluoride (AlFx), alucone polymer film, titanium nitride (TiN), tantalum nitride (TaN), aluminum nitride (AlNx), gallium nitride (GaN), tungsten nitride (WN), hafnium nitride (HfN), niobium nitride (NbN), gadolinium nitride (GdN), zirconium nitride (ZrN), vanadium nitride (VN), and the like. However, the disclosure is not limited thereto, and various materials having insulating properties may be used as the material of the insulating film 14.

In an embodiment, the insulating film 14 may be provided in the form of a single layer or in the form of multiple layers including a double layer.

The light emitting element LD described above may be used as a light emitting source (or light source) of various display devices. The light emitting element LD may be manufactured through a surface treatment process. For example, in case that light emitting elements LD are mixed with a liquid solution (or solvent) and supplied to each pixel area (for example, an emission area of each pixel or an emission area of each sub-pixel), each of the light emitting elements LD may be surface-treated so that the light emitting elements LD may be uniformly sprayed without uneven aggregation in the solution.

A light emitting part (or light emitting device) including the light emitting elements LD described above may be used in various types of electronic devices requiring a light source, including a display device. For example, in case that light emitting elements LD are disposed in a pixel area of each pixel of a display panel, the light emitting elements LD may be used as a light source of each pixel. However, the field to which the light emitting element LD is applied is not limited to the above-described example. For example, the light emitting element LD may also be used in other types of electronic devices requiring a light source, such as a lighting device.

However, this is only an example, and the light emitting element LD applied to a display device according to embodiments of the disclosure is not limited thereto. For example, the light emitting element LD may be a flip chip type micro light emitting diode or an organic light emitting element including an organic light emitting layer.

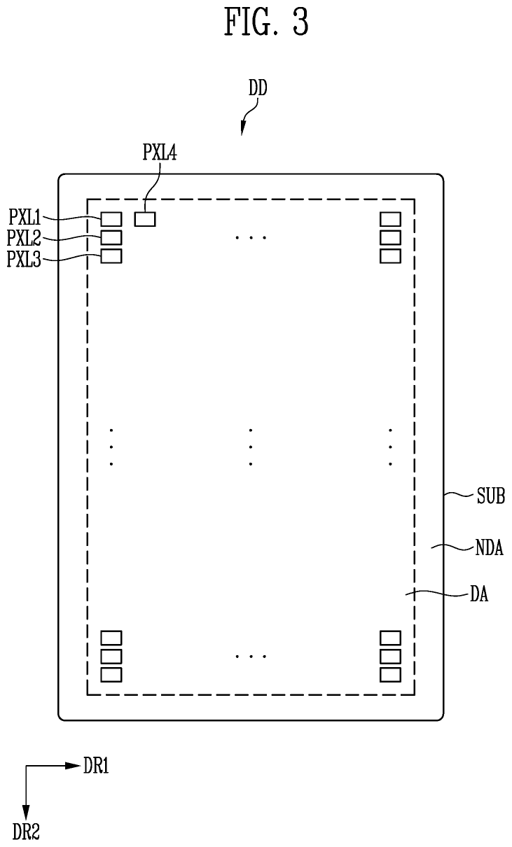

FIG. 3 is a plan view schematically illustrating a display device according to embodiments of the disclosure.

Referring to FIGS. 1, 2, and 3, a display device DD may include pixels PXL1, PXL2, PXL3, and PXL4 provided on a substrate SUB and each including at least one light emitting element LD. The pixels PXL1, PXL2, PXL3, and PXL4 may include the light emitting element (for example, the light emitting element LD of FIG. 1). The display device DD may further include a driver and a wiring part electrically connected to the driver.

The substrate SUB may include a display area DA and a non-display area NDA.

The display area DA may be an area where an image is displayed and the pixels PXL1, PXL2, PXL3, and PXL4 may or may not emit light. The non-display area NDA may be an area in which the driver for driving the pixels PXL1, PXL2, PXL3, and PXL4 and a part of the wiring part for electrically connecting the pixels PXL1, PXL2, PXL3, and PXL4 to the driver are provided.

The non-display area NDA may be located adjacent to the display area DA. The non-display area NDA may be provided on at least one side of the display area DA. For example, the non-display area NDA may surround the periphery (or edge) of the display area DA.

The wiring part may include signal lines. The signal lines may be electrically connected to the pixels PXL1, PXL2, PXL3, and PXL4 to provide signals. The signal lines may include fan-out lines electrically connected to scan lines, data lines, emission control lines, and the like.

In an embodiment, the pixels PXL1, PXL2, PXL3, and PLX4 may include a first pixel PXL1, a second pixel PXL2, a third pixel PXL3, and a fourth pixel PXL4. In an example, the first to third pixels PXL1 to PXL3 may be pixels emitting light of a same color. For example, the first to third pixels PXL1 to PXL3 may be at least one of a red pixel, a green pixel, and a blue pixel. In an example, the fourth pixel PXL4 may emit light of a different color from the first pixel PXL1. For example, in case that the first pixel PXL1 is a red pixel emitting red light, the fourth pixel PXL4 may be a green pixel emitting green light or a blue pixel emitting blue light. However, the disclosure is not limited thereto, and the fourth pixel PXL4 and the first pixel PXL1 may emit light of a same color.

In an embodiment, the first pixel PXL1, the second pixel PXL2, and the third pixel PXL3 may be sequentially arranged in a second direction DR2. The fourth pixel PXL4 may be disposed to be spaced apart from the first pixel PXL1 in a first direction DR1.

The light emitting element LD may have a size as small as a nano-scale (or nanometer) to micro-scale (or micrometer), and may be electrically connected in parallel with light emitting elements LD disposed adjacent thereto, but the disclosure is not limited thereto. The light emitting element LD may constitute (or form) a light source for each of the pixels PXL1, PXL2, PXL3, and PXL4.

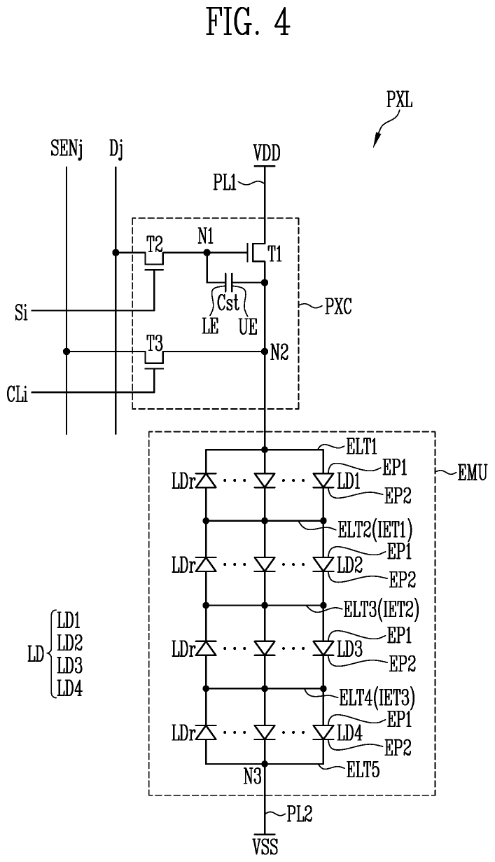

FIG. 4 is a schematic diagram of an equivalent circuit illustrating an example of a pixel included in the display device of FIG. 3 in case that the pixel is in a normal state.

A pixel PXL shown in FIG. 4 may be any one of the first pixel PXL1, the second pixel PXL2, and the third pixel PXL3 of FIG. 3.

Referring to FIGS. 1, 2, 3, and 4, the pixel PXL may include a pixel circuit PXC and an emission part EMU.

The pixel PXL may include the pixel circuit PXC that controls a driving current based on a data signal and the emission part EMU that emits light with a luminance corresponding to the driving current.

The emission part EMU may be electrically connected to a first driving power source VDD and a second driving power source VSS through a corresponding pixel circuit PXC and may be turned on.

A case in which the emission part EMU is electrically connected to the first driving power source VDD and the second driving power source VSS through the corresponding pixel circuit PXC and turned on may be referred to as a case in which the pixel PXL is in a normal state. A case in which the emission part EMU is not turned on because the emission part EMU is not electrically connected to the first driving power source VDD due to a defect in the corresponding pixel circuit PXC may be referred to as a case in which the pixel PXL is in a defective state.

In an embodiment, the emission part EMU may include light emitting elements LD electrically connected in parallel between a first power source line PL1 and a second power source line PL2. The first power source line PL1 may be electrically connected to the first driving power source VDD, and a voltage of the first driving power source VDD may be applied to the first power source line PL1. The second power source line PL2 may be electrically connected to the second driving power source VSS, and a voltage of the second driving power source VSS may be applied to the second power source line PL2. For example, the emission part EMU may include light emitting elements LD electrically connected in parallel to each other in a same direction between first and fifth pixel electrodes ELT1 and ELT5.

The first driving power source VDD and the second driving power source VSS may have different potentials. As an example, the first driving power source VDD may be set to a high-potential power source, and the second driving power source VSS may be set to a low-potential power source. A potential difference between the first and second driving power sources VDD and VSS may be set to be higher than or equal to a threshold voltage of the light emitting elements LD during an emission period of the pixel PXL.

The first pixel electrode ELT1 may be electrically connected to the first driving power source VDD through the pixel circuit PXC and the first power source line PL1, and the fifth pixel electrode ELT5 may be electrically connected to the second driving power source VSS through the second power source line PL2. In an embodiment, the first pixel electrode ELT1 may be an anode, and the fifth pixel electrode ELT5 may be a cathode.

Hereinafter, in case that one or more light emitting elements among first to fourth light emitting elements LD1, LD2, LD3, and LD4 is arbitrarily referred to, or two or more types of light emitting elements are comprehensively referred to, they will be referred to as “light emitting element LD” or “light emitting elements LD”.

In an embodiment, each of the light emitting elements LD may include a first end electrically connected to the first driving power source VDD through the first pixel electrode ELT1 and a second end electrically connected to the second driving power source VSS through the fifth pixel electrode ELT5.

As described above, each of the light emitting elements LD electrically connected in parallel in a same direction (for example, forward direction) between the first pixel electrode ELT1 and the fifth pixel electrode ELT5 to which voltages of different power sources are supplied may constitute an effective light source.

In an embodiment, the light emitting elements LD of the emission part EMU may emit light with a luminance corresponding to a driving current supplied through the corresponding pixel circuit PXC. For example, during each frame period, the pixel circuit PXC may supply the driving current corresponding to a grayscale value of corresponding frame data to the emission part EMU. The driving current supplied to the emission part EMU may be divided and flowed to each of the light emitting elements LD. Accordingly, while each light emitting element LD emits light with a luminance corresponding to a current flowing therethrough, the emission part EMU may emit light with a luminance corresponding to the driving current.

In the above-described embodiment, a case in which ends of the light emitting elements LD are electrically connected in a same direction between the first and second driving power sources VDD and VSS has been described, but the disclosure is not limited thereto. According to an embodiment, the emission part EMU may further include at least one ineffective light source, for example, a reverse light emitting element LDr, in addition to the light emitting elements LD constituting the effective light source.

The reverse light emitting element LDr may be electrically connected in parallel between the first and fifth pixel electrodes ELT1 and ELT5 together with the light emitting elements LD constituting the effective light source, but may be electrically connected between the first and fifth pixel electrodes ELT1 and ELT5 in an opposite direction to the light emitting elements LD. The reverse light emitting element LDr may be maintained in an inactive state even in case that a driving voltage (for example, a predetermined or selectable driving voltage), for example, a forward driving voltage is applied between the first and fifth pixel electrodes ELT1 and ELT5. Accordingly, no current may substantially flow through the reverse light emitting element LDr.

The pixel circuit PXC may be electrically connected to a scan line Si and a data line Dj. The pixel circuit PXC may be electrically connected to a control line CLi and a sensing line SENj. As an example, in case that the pixel PXL is disposed in an i-th row and a j-th column of the display area DA, the pixel circuit PXC of the pixel PXL may be electrically connected to an i-th scan line Si, a j-th data line Dj, an i-th control line CLi, and a j-th sensing line SENj.

In an embodiment, the pixel circuit PXC may include first to third transistors T1 to T3 and a storage capacitor Cst.

The first transistor T1 may be a driving transistor for controlling the driving current applied to the emission part EMU, and may be electrically connected between the first driving power source VDD and the emission part EMU. A first terminal of the first transistor T1 may be electrically connected to the first driving power source VDD through the first power source line PL1, a second terminal of the first transistor T1 may be electrically connected to a second node N2, and a gate electrode of the first transistor T1 may be electrically connected to a first node N1. The first transistor T1 may control the amount of a driving current applied from the first driving power source VDD to the emission part EMU through the second node N2 according to a voltage applied to the first node N1. The first terminal of the first transistor T1 may be a drain electrode, and the second terminal of the first transistor T1 may be a source electrode, but the disclosure is not limited thereto. According to an embodiment, the first terminal may be a source electrode, and the second terminal may be a drain electrode.

The second transistor T2 may be a switching transistor that selects (or activates) the pixel PXL in response to a scan signal, and may be electrically connected between the data line Dj and the first node N1. A first terminal of the second transistor T2 may be electrically connected to the data line Dj, a second terminal of the second transistor T2 may be electrically connected to the first node N1, and a gate electrode of the second transistor T2 may be electrically connected to the scan line Si. In case that the first terminal is a drain electrode, the second terminal may be a source electrode, but the disclosure is not limited thereto.

The second transistor T2 may be turned on in case that the scan signal having a gate-on voltage (for example, a high-level voltage) is supplied from the scan line Si to electrically connect the data line Dj and the first node N1. The first node N1 may be a point where the second terminal of the second transistor T2 and the gate electrode of the first transistor T1 are electrically connected to each other, and the second transistor T2 may transfer the data signal to the gate electrode of the first transistor T1.

In an embodiment, a second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line CLi.

In an embodiment, the first terminal of the third transistor T3 may be electrically connected to an initialization power source. The third transistor T3 may be an initialization transistor capable of initializing the second node N2, and may be turned on in case that a sensing control signal is supplied from the control line CLi to transfer a voltage of the initialization power source applied to the sensing line SENj to the second node N2. Accordingly, a second storage electrode of the storage capacitor Cst electrically connected to the second node N2 may be initialized.

In another embodiment, the third transistor T3 may obtain a sensing signal through the sensing line SENj by electrically connecting the first transistor T1 to the sensing line SENj, and may detect characteristics of the pixel PXL including a threshold voltage of the first transistor T1 and the like using the sensing signal. Information on the characteristics of the pixel PXL may be used to convert image data so that characteristic deviations between the pixels PXL can be compensated for.

In an embodiment, a first storage electrode LE of the storage capacitor Cst may be electrically connected to the first node N1, and a second storage electrode UE of the storage capacitor Cst may be electrically connected to the second node N2. The storage capacitor Cst may be charged with a data voltage corresponding to the data signal supplied to the first node N1 during a frame period. The storage capacitor Cst may store a voltage corresponding to a difference between a voltage of the gate electrode of the first transistor T1 and a voltage of the second node N2.

In an embodiment, the emission part EMU may be configured to include at least one serial stage including light emitting elements LD electrically connected to each other in parallel. In an example, the emission part EMU may have a serial or parallel mixed structure. For example, the emission part EMU may have a 4 serial stage structure including four serial stages. However, the disclosure it is not limited thereto, and the emission part EMU may have a 2 serial stage structure including two serial stages or a 6 serial stage structure including six serial stages.

In an embodiment, each serial stage may include a pair of electrodes (for example, two electrodes) and at least one light emitting element LD electrically connected in a forward direction between the pair of electrodes. The number of light emitting elements LD constituting each serial stage is not particularly limited. As an example, the number of light emitting elements LD constituting each serial stage may be the same or different, and the number of light emitting elements LD is not particularly limited.

In an embodiment, the emission part EMU may include a first serial stage, a second serial stage, a third serial stage, and a fourth serial stage.

In an embodiment, the first serial stage may include a first pixel electrode ELT1, a second pixel electrode ELT2, and at least one first light emitting element LD1 electrically connected between the first and second pixel electrodes ELT1 and ELT2. Each first light emitting element LD1 may be electrically connected in a forward direction between the first and second pixel electrodes ELT1 and ELT2. For example, a first end EP1 of the first light emitting element LD1 may be electrically connected to the first pixel electrode ELT1, and a second end EP2 of the first light emitting element LD1 may be electrically connected to the second pixel electrode ELT2.

In an embodiment, the second serial stage may include the second pixel electrode ELT2, a third pixel electrode ELT3, and at least one second light emitting element LD2 electrically connected between the second and third pixel electrodes ELT2 and ELT3. Each second light emitting element LD2 may be electrically connected in a forward direction between the second and third pixel electrodes ELT2 and ELT3. For example, a first end EP1 of the second light emitting element LD2 may be electrically connected to the second pixel electrode ELT2, and a second end EP2 of the second light emitting element LD2 may be electrically connected to the third pixel electrode ELT3.

In an embodiment, the third serial stage may include the third pixel electrode ELT3, a fourth pixel electrode ELT4, and at least one third light emitting element LD3 electrically connected between the third and fourth pixel electrodes ELT3 and ELT4. Each third light emitting element LD3 may be electrically connected in a forward direction between the third and fourth pixel electrodes ELT3 and ELT4. For example, a first end EP1 of the third light emitting element LD3 may be electrically connected to the third pixel electrode ELT3, and a second end EP2 of the third light emitting element LD3 may be electrically connected to the fourth pixel electrode ELT4.

In an embodiment, the fourth serial stage may include the fourth pixel electrode ELT4, a fifth pixel electrode ELT5, and at least one fourth light emitting element LD4 electrically connected between the fourth and fifth pixel electrodes ELT4 and ELT5. Each fourth light emitting element LD4 may be electrically connected in a forward direction between the fourth and fifth pixel electrodes ELT4 and ELT5. For example, a first end EP1 of the fourth light emitting element LD4 may be electrically connected to the fourth pixel electrode ELT4, and a second end EP2 of the fourth light emitting element LD4 may be electrically connected to the fifth pixel electrode ELT5.

In an embodiment, the first pixel electrode ELT1 of the first serial stage may be an anode electrode of each pixel PXL, and the fifth pixel electrode ELT5 of the fourth serial stage may be a cathode electrode of each pixel PXL.

In an embodiment, the remaining electrodes of the emission part EMU, for example, the second pixel electrode ELT2, the third pixel electrode ELT3, and/or the fourth pixel electrode ELT4 may constitute intermediate electrodes. For example, the second pixel electrode ELT2 may constitute a first intermediate electrode IET1, the third pixel electrode ELT3 may constitute a second intermediate electrode IET2, and the fourth pixel electrode ELT4 may constitute a third intermediate electrode IET3.

In an embodiment, at least one of the first to fourth serial stages may include a reverse light emitting element LDr electrically connected in an opposite direction to the first to fourth light emitting elements LD1, LD2, LD3, and LD4 between the two electrodes.

In an embodiment, the first pixel electrode ELT1 may be electrically connected to the pixel circuit PXC through the second node N2. The fifth pixel electrode ELT5 may be electrically connected to the second power source line PL2 through a third node N3. In an example, the second node N2 may be a first point at which the pixel circuit PXC and the emission part EMU are electrically connected to each other, and the third node N3 may be a second point at which the pixel circuit PXC and the emission part EMU are electrically connected to each other.

In an embodiment, the first transistor T1, the second transistor T2, and the third transistor T3 may be oxide semiconductor transistors. The first transistor T1, the second transistor T2, and the third transistor T3 may include an oxide semiconductor layer as an active layer (a semiconductor layer or a channel layer). For example, the first transistor T1, the second transistor T2, and the third transistor T3 may include n-type oxide semiconductor transistors. However, the disclosure is not limited thereto. For example, the first transistor T1, the second transistor T2, and the third transistor T3 may be implemented as p-type semiconductor transistors.

An oxide semiconductor transistor may be manufactured through a low-temperature process and may have lower charge mobility than a polysilicon semiconductor transistor. For example, the oxide semiconductor transistor has excellent off current characteristics. Therefore, in case that the first transistor T1, the second transistor T2, and the third transistor T3 are composed of oxide semiconductor transistors, leakage current through the first transistor T1, the second transistor T2, and the third transistor T3 can be minimized by means of low-frequency driving and variable-frequency driving. Accordingly, display quality may be improved.

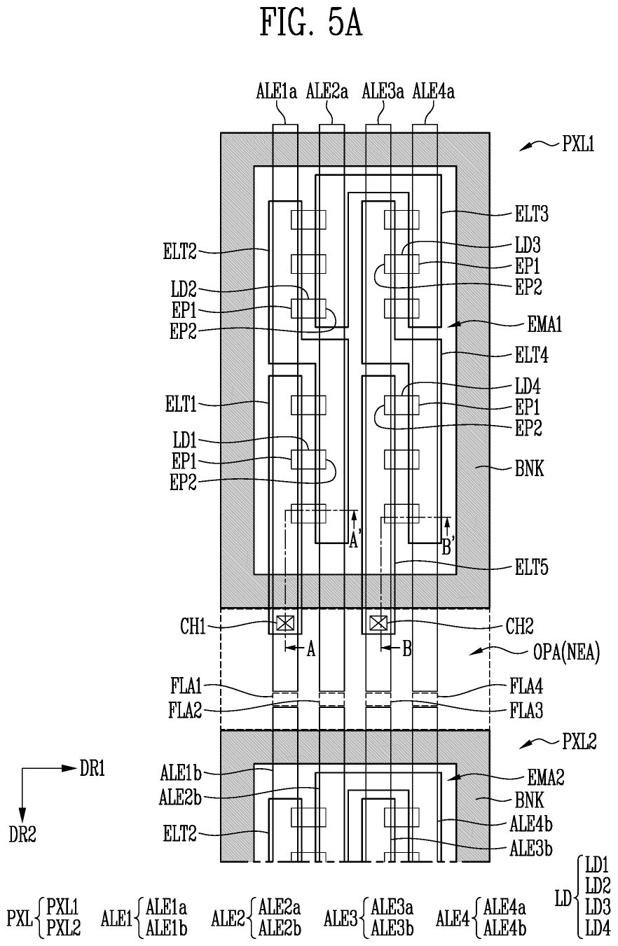

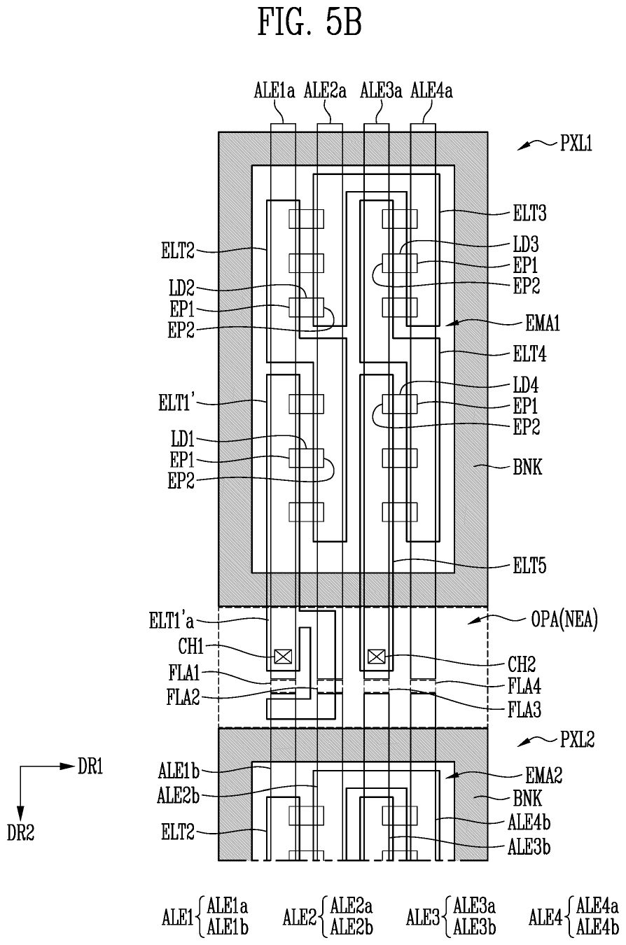

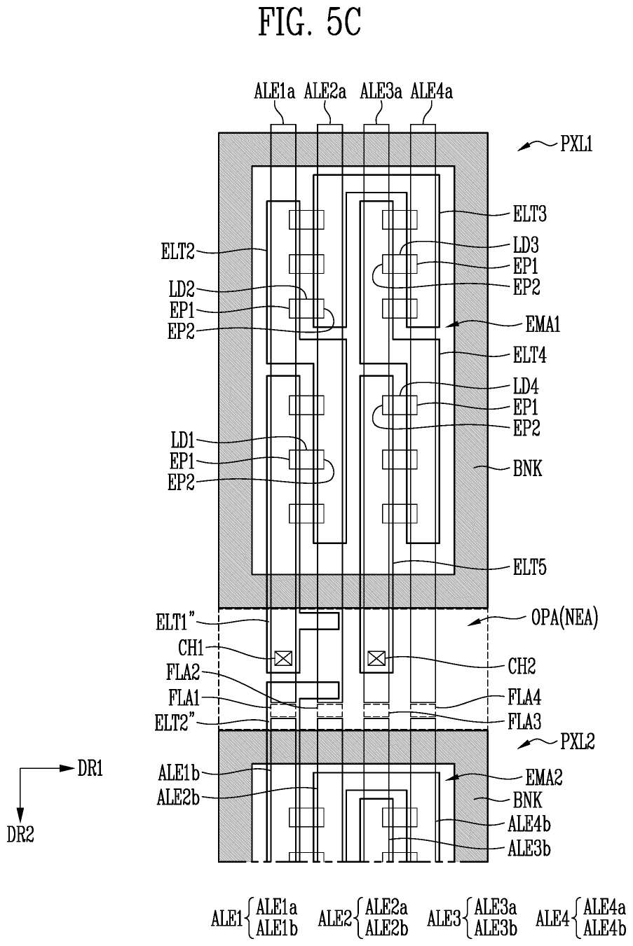

FIG. 5A is a plan view schematically illustrating an example of the pixel of FIG. 4.

FIG. 5A is a schematic plan view illustrating the first pixel PXL1 as a pixel included in the display device DD. For convenience of description, FIGS. 5A to 5C illustrate the first pixel PXL1 and a part of the second pixel PXL2 adjacent thereto. FIGS. 5A to 5C illustrate an embodiment in which each pixel PXL includes light emitting elements LD disposed in four serial stages as shown in FIG. 4, but the number of serial stages of each pixel PXL may be variously changed according to embodiments.

Referring to FIGS. 3, 4, and 5A, the display device DD may include a bank BNK, first to fourth alignment electrodes ALE1 to ALE4, the light emitting elements LD1 to LD4, and the pixel electrodes ELT1 to ELT5 to configure the pixels PXL1 and PXL2.

In an embodiment, the first pixel PXL1 and the second pixel PXL2 may have a same or similar structures. Since the second pixel PXL2 may be substantially similar to the first pixel PXL1, the first pixel PXL1 will be described.

In an embodiment, the bank BNK may divide the first pixel PXL1 and the second pixel PXL2. The pixel PXL may include an emission area and a non-emission area NEA. The first pixel PXL1 may include a first emission area EMA1, and the second pixel PXL2 may include a second emission area EMA2. The non-emission area NEA may be formed between the first emission area EMA1 and the second emission area EMA2. In an example, the first emission area EMA1 and the second emission area EMA2 may correspond to openings defined by the bank BNK. The non-emission area NEA may correspond to an opening area OPA formed in the bank BNK. The bank BNK may surround the emission areas EMA1 and EMA2. In an example, the opening area OPA may be an area distinct from the openings corresponding to the first and second emission areas EMA1 and EMA2.

In an embodiment, the first to fourth alignment electrodes ALE1 to ALE4 may be sequentially arranged to be spaced apart from each other in the first direction DR1 and may extend in the second direction DR2. The first to fourth alignment electrodes ALE1 to ALE4 may be electrodes for aligning the light emitting elements LD provided in the first pixel PXL1 and the second pixel PXL2. The light emitting elements LD may be moved (or rotated) by a force (for example, dielectrophoresis (DEP) force) according to an electric field and aligned (or disposed) on the alignment electrodes. The first pixel PXL1 and the second pixel PXL2 may share the first to fourth alignment electrodes ALE1 to ALE4 in a process of manufacturing the pixels.

In an embodiment, the first to fourth alignment electrodes ALE1 to ALE4 may be supplied (or provided) with a first alignment signal or a second alignment signal, respectively, in a process of aligning the light emitting elements LD (hereinafter referred to as an alignment process).

In an embodiment, the first alignment signal and the second alignment signal may have different waveforms, potentials, and/or phases. The first alignment signal may be a ground signal, and the second alignment signal may be an AC signal. However, the disclosure is not limited to the above examples. For example, the first alignment signal may be an AC signal and the second alignment signal may be a ground signal.

In an embodiment, different alignment signals may be applied to adjacent alignment electrodes among the alignment electrodes. In an example, in case that the first alignment signal may be applied to the first alignment electrode ALE1, the second alignment signal may be applied to the second alignment electrode ALE2. In case that the first alignment signal is applied to the second alignment electrode ALE2, the second alignment signal may be applied to the first alignment electrode ALE1. In case that the first alignment signal is applied to the third alignment electrode ALE3, the second alignment signal may be applied to the fourth alignment electrode ALE4.

In an embodiment, an electric field may be formed between (or on) the first alignment electrode ALE1 and the second alignment electrode ALE2, and first light emitting elements LD1 and second light emitting elements LD2 may be aligned on the first alignment electrode ALE1 and the second alignment electrode ALE2 based on the electric field.

In an embodiment, an electric field may be formed between (or on) the third alignment electrode ALE3 and the fourth alignment electrode ALE4, and third light emitting elements LD3 and fourth light emitting elements LD4 may be aligned on the third alignment electrode ALE3 and the fourth alignment electrode ALE4 based on the electric field.

In an embodiment, the first light emitting elements LD1 may be aligned between the first and second alignment electrodes ALE1 and ALE2. In an example, the first light emitting elements LD1 may be aligned in an area (for example, a lower area) of the first and second alignment electrodes ALE1 and ALE2, first ends EP1 of the first light emitting elements LD1 may be electrically connected to the first pixel electrode ELT1, and second ends EP2 of the first light emitting elements LD1 may be electrically connected to the second pixel electrode ELT2.

In an embodiment, the second light emitting elements LD2 may be aligned between the first and second alignment electrodes ALE1 and ALE2. In an example, the second light emitting elements LD2 may be aligned in another area (for example, an upper area) of the first and second alignment electrodes ALE1 and ALE2, first ends EP1 of the second light emitting elements LD2 may be electrically connected to the second pixel electrode ELT2, and second ends EP2 of the second light emitting elements LD2 may be electrically connected to the third pixel electrode ELT3.

In an embodiment, the third light emitting elements LD3 may be aligned between the third and fourth alignment electrodes ALE3 and ALE4 and electrically connected between the third and fourth pixel electrodes ELT3 and ELT4. In an example, the third light emitting elements LD3 may be aligned in another area (for example, an upper area) of the third and fourth alignment electrodes ALE3 and ALE4, first ends EP1 of the third light emitting elements LD3 may be electrically connected to the third pixel electrode ELT3, and second ends EP2 of the third light emitting elements LD3 may be electrically connected to the fourth pixel electrode ELT4.

In an embodiment, the fourth light emitting elements LD4 may be aligned between the third and fourth alignment electrodes ALE3 and ALE4 and electrically connected between the fourth and fifth pixel electrodes ELT4 and ELT5. In an example, the fourth light emitting elements LD4 may be aligned in an area (for example, a lower area) of the third and fourth alignment electrodes ALE3 and ALE4, first ends EP1 of the fourth light emitting elements LD4 may be electrically connected to the fourth pixel electrode ELT4, and second ends EP2 of the fourth light emitting elements LD4 may be electrically connected to the fifth pixel electrode ELT5.

In an embodiment, the first light emitting elements LD1 may be positioned in a lower left area of the first emission area EMA1, and the second light emitting elements LD2 may be positioned in an upper left area of the first emission area EMA1. The third light emitting elements LD3 may be positioned in an upper right area of the first emission area EMA1, and the fourth light emitting elements LD4 may be positioned in a lower right area of the first emission area EMA1. However, the arrangement and/or connection structure of the light emitting elements may be variously changed according to the structure of the emission part (for example, the emission part EMU of FIG. 4) and/or the number of serial stages.

In an embodiment, some of the first to fourth alignment electrodes ALE1 to ALE4 may be electrically connected to some of the pixel electrodes ELT1 to ELT5 through contact holes. For example, the first alignment electrode ALE1 may be electrically connected to the first pixel electrode ELT1 through a first contact hole CH1 located in the non-emission area NEA, and the third alignment electrode ALE3 may be electrically connected to the fifth pixel electrode ELT5 through a second contact hole CH2 located in the non-emission area NEA.

In an embodiment, after the light emitting elements LD1, LD2, LD3, and LD4 are supplied and aligned in the first emission area EMA1 and the second emission area EMA2, at least one of the first to fourth alignment electrodes ALE1 to ALE4 may be separated from the alignment electrodes ALE1 to ALE4 provided in the second pixel PXL2 adjacent to the first pixel PXL1.

A first dummy electrode ALE1a provided in the first pixel PXL1 and a first dummy electrode ALE1b provided in the second pixel PXL2 may be integrally connected (or integral with each other) to form the first alignment electrode ALE1. The first dummy electrode ALE1a may be electrically connected to the pixel circuit (for example, the pixel circuit PXC of FIG. 4) and/or the first power source line PL1 through a contact hole. The first alignment signal (or the second alignment signal) may be supplied to the first alignment electrode ALE1 through the pixel circuit or the first power source line PL1. After the process of aligning the light emitting elements LD is completed, the first alignment electrode ALE1 may be separated into the first dummy electrode ALE1a of the first pixel PXL1 and the first dummy electrode ALE1b of the second pixel PXL2 by removing the first alignment electrode ALE1 from a first floating area FLA1 located around the first dummy electrode ALE1a.

In an embodiment, a second dummy electrode ALE2a provided in the first pixel PXL1 and a second dummy electrode ALE2b provided in the second pixel PXL2 may be integrally connected (or integral with each other) to form the second alignment electrode ALE2. The second alignment signal (or the first alignment signal) may be supplied to the second dummy electrode ALE2a through a contact hole (not shown). After the process of aligning the light emitting elements LD is completed, the second alignment electrode ALE2 may be separated into the second dummy electrode ALE2a of the first pixel PXL1 and the second dummy electrode ALE2b of the second pixel PXL2 by removing the second alignment electrode ALE2 from a second floating area FLA2 located around the second dummy electrode ALE2a in the non-emission area NEA. An electrical connection between the second dummy electrode ALE2a of the first pixel PXL1 and the second dummy electrode ALE2b of the second pixel PXL2 may be disconnected.

In an embodiment, a third dummy electrode ALE3a provided in the first pixel PXL1 and a third dummy electrode ALE3b provided in the second pixel PXL2 may be integrally connected (or integral with each other) to form the third alignment electrode ALE3. The third dummy electrode ALE3a may be electrically connected to the pixel circuit PXC and/or the second power source line PL2 through a contact hole. The second alignment signal (or the first alignment signal) may be supplied to the third dummy electrode ALE3a through the pixel circuit PXC and/or the second power source line PL2. After the process of aligning the light emitting elements LD is completed, the third alignment electrode ALE3 may be separated into the third dummy electrode ALE3a of the first pixel PXL1 and the third dummy electrode ALE3b of the second pixel PXL2 by removing the third alignment electrode ALE3 from a third floating area FLA3 located around the third dummy electrode ALE3a.

In an embodiment, a fourth dummy electrode ALE4a provided in the first pixel PXL1 and a fourth dummy electrode ALE4b provided in the second pixel PXL2 may be integrally connected (or integral with each other) to form the fourth alignment electrode ALE4. The second alignment signal (or the first alignment signal) may be supplied to the fourth dummy electrode ALE4a through a contact hole (not shown). After the process of aligning the light emitting elements LD is completed, the fourth alignment electrode ALE4 may be separated into the fourth dummy electrode ALE4a of the first pixel PXL1 and the fourth dummy electrode ALE4b of the second pixel PXL2 by removing the fourth alignment electrode ALE4 from a fourth floating area FLA4 located around the fourth dummy electrode ALE4a in the non-emission area NEA. An electrical connection between the fourth dummy electrode ALE4a of the first pixel PXL1 and the fourth dummy electrode ALE4b of the second pixel PXL2 may be disconnected.

In an embodiment, through the process of separating each of the first to fourth alignment electrodes ALE1 to ALE4, the first to fourth alignment electrodes ALE1 to ALE4 may be separated into the first to fourth dummy electrodes ALE1a to ALE4a overlapping the first emission area EMA1 of the first pixel PXL and the first to fourth dummy electrodes ALE1b to ALE4b overlapping the second emission area EMA2 of the second pixel PXL2 in a view or direction (e.g., in a plan view).

In an embodiment, the dummy electrodes ALE1a to ALE4a of the first pixel PXL1 may be provided in at least the first emission area EMA1. The dummy electrodes ALE1a to ALE4a may extend in the second direction DR2 and may be spaced apart from each other in the first direction DR1. The dummy electrodes ALE1a to ALE4a may extend from the first emission area EMA1 to the non-emission area NEA. For example, the dummy electrodes ALE1a to ALE4a may extend from the first emission area EMA1 to the opening area OPA. The first to fourth dummy electrodes ALE1a, ALE2a, ALE3a, and ALE4a may extend in the second direction DR2 and may be sequentially arranged in the first direction DR1 to be spaced apart from each other.

In an embodiment, an electrical connection between the first dummy electrode ALE1b and the first power source line PL1 may be disconnected by removing a portion of the first alignment electrode ALE1 around the contact hole located in the non-emission area NEA. An electrical connection between the third dummy electrode ALE3b and the second power source line PL2 may be disconnected by removing a portion of the third alignment electrode ALE3 around the contact hole located in the non-emission area NEA.

In an embodiment, the opening area OPA may refer to an area including a spaced area between the dummy electrodes ALE1a to ALE4a and ALE1b to ALE4b included in each of the first and second pixels PXL1 and PXL2.

In an embodiment, the dummy electrodes ALE1a to ALE4a of the first pixel PXL1 and the dummy electrodes ALE1b to ALE4b of the second pixel PXL2 may be provided in a bar shape having a constant width in the emission areas EMA1 and EMA2, but the disclosure is not limited thereto. The dummy electrodes ALE1a to ALE4a of the first pixel PXL1 and the dummy electrodes ALE1b to ALE4b of the second pixel PXL2 may have a bar shape having a constant width or a shape having a bent portion in the non-emission area NEA, but the shape and/or size thereof in the remaining areas other than the emission areas EMA1 and EMA2 is not particularly limited and may be variously changed.

In an embodiment, the first to fifth pixel electrodes ELT1 to ELT5 may be provided in each of the emission areas EMA1 and EMA2, and may be disposed to overlap one or more dummy electrodes ALE1a to ALE4a and ALE1b to ALE4b and/or light emitting elements LD1 to LD4. For example, each of the pixel electrodes ELT1 to ELT5 may be formed on the dummy electrodes ALE1a to ALE4a and ALE1b to ALE4b and/or the light emitting elements LD1 to LD4 to overlap the dummy electrodes ALE1a to ALE4a and ALE1b to ALE4b and/or the light emitting elements LD1 to LD4, and may be electrically connected to the light emitting elements.

In an embodiment, the first pixel electrode ELT1 may be disposed on an area (for example, a lower area) of the first dummy electrode ALE1a and the first ends EP1 of the first light emitting elements LD1, and may be electrically connected to the first ends EP1 of the first light emitting elements LD1.

In an embodiment, the second pixel electrode ELT2 may be disposed on an area (for example, a lower area) of the second dummy electrode ALE2a and the second ends EP2 of the first light emitting elements LD1, and may be electrically connected to the second ends EP2 of the second light emitting elements LD2. The second pixel electrode ELT2 may be disposed on another area (for example, an upper area) of the first dummy electrode ALE1a and the first ends EP1 of the second light emitting elements LD2, and may be electrically connected to the first ends EP1 of the second light emitting elements LD2. For example, the second pixel electrode ELT2 may electrically connect the second ends EP2 of the first light emitting elements LD1 and the first ends EP1 of the second light emitting elements LD2 in the first emission area EMA1. To this end, the second pixel electrode ELT2 may have a bent shape. For example, the second pixel electrode ELT2 may have a structure bent or curved at a boundary between an area where at least one first light emitting element LD1 is arranged and an area where at least one second light emitting element LD2 is arranged.

In an embodiment, the third pixel electrode ELT3 may be disposed on another area (for example, an upper area) of the second dummy electrode ALE2a and the second ends EP2 of the second light emitting elements LD2, and may be electrically connected to the second ends EP2 of the second light emitting elements LD2. The third pixel electrode ELT3 may be disposed on another area (for example, an upper area) of the fourth dummy electrode ALE4a and the first ends EP1 of the third light emitting elements LD3, and may be electrically connected to the first ends EP1 of the third light emitting elements LD3. For example, the third pixel electrode ELT3 may electrically connect the second ends EP2 of the second light emitting elements LD2 and the first ends EP1 of the third light emitting elements LD3 in the first emission area EMA1. To this end, the third pixel electrode ELT3 may have a bent shape. For example, the third pixel electrode ELT3 may have a structure bent or curved at a boundary between an area where at least one second light emitting element LD2 is arranged and an area where at least one third light emitting element LD3 is arranged.

In an embodiment, the fourth pixel electrode ELT4 may be disposed on another area (for example, an upper area) of the third dummy electrode ALE3a and the second ends EP2 of the third light emitting elements LD3, and may be electrically connected to the second ends EP2 of the third light emitting elements LD3. The fourth pixel electrode ELT4 may be disposed on an area (for example, a lower area) of the fourth dummy electrode ALE4a and the first ends EP1 of the fourth light emitting elements LD4, and may be electrically connected to the first ends EP1 of the fourth light emitting elements LD4. For example, the fourth pixel electrode ELT4 may electrically connect the second ends EP2 of the third light emitting elements LD3 and the first ends EP1 of the fourth light emitting elements LD4 in the first emission area EMA1. To this end, the fourth pixel electrode ELT4 may have a bent shape. For example, the fourth pixel electrode ELT4 may have a structure bent or curved at a boundary between an area where at least one third light emitting element LD3 is arranged and an area where at least one fourth light emitting element LD4 is arranged.

In an embodiment, the fifth pixel electrode ELT5 may be disposed on an area (for example, a lower area) of the third dummy electrode ALE3a and the second ends EP2 of the fourth light emitting elements LD4, and may be electrically connected to the second ends EP2 of the fourth light emitting elements LD4.

In the same way as described above, the first to fourth light emitting elements LD1 to LD4 aligned between the dummy electrodes ALE1a to ALE4a may be electrically connected in a desired form using the pixel electrodes ELT1 to ELT5. For example, the first light emitting elements LD1, the second light emitting elements LD2, the third light emitting elements LD3, and the fourth light emitting elements LD4 may be sequentially electrically connected in series using the pixel electrodes ELT1 to ELT5.

FIGS. 5B and 5C are plan views schematically illustrating other examples of the pixel of FIG. 4.

Referring to FIGS. 5A and 5B, at least a first pixel electrode ELT1′ of the first pixel PXL1 may be distinguishable from that shown in FIG. 5A. The same reference numerals are used for the same or corresponding components, and duplicate descriptions will be omitted.

The first pixel electrode ELT1 and the fifth pixel electrode ELT5 of FIG. 5A may extend from the first emission area EMA1 to the non-emission area NEA and may be provided in a bar shape having a constant width.

The first pixel electrode ELT1′ of FIG. 5B may include a bar shape having a constant width and a shape protruding in a direction from the bar shape to have a bent portion. A portion of the first pixel electrode ELT1′ having a bar shape may extend from the first emission area EMA1 to the non-emission area NEA. A portion of the first pixel electrode ELT1′ having the bent portion may be provided in the non-emission area NEA.

An embodiment illustrates a case in which a portion of the first pixel electrode ELT1′ having a bent portion is electrically connected to the first pixel electrode ELT1′ having a bar shape and protrudes in the first direction DR1, but the disclosure is not limited thereto. The portion of the first pixel electrode ELT1′ having a bent portion may protrude in a direction opposite to the first direction DR1 with respect to the first pixel electrode ELT1′ having a bar shape.

In an embodiment, the first pixel electrode ELT1′ may extend from the first emission area EMA1 to the non-emission area NEA, and may include a first portion disposed on the first dummy electrode ALE1a and connected to (or extended to) the first contact hole CH1, a second portion extending or protruding in the first direction DR1 from the first portion to be disposed on the second dummy electrode ALE2b, and a third portion extending from the second portion and disposed on the first dummy electrode ALE1b of the second pixel PXL2.

In an embodiment, the second portion of the first pixel electrode ELT1′ may overlap a region of the second dummy electrode ALE2a of the first pixel PXL1 and a region of the second dummy electrode ALE2b of the second pixel PXL2. In an example, the first contact hole CH1 formed in the first portion of the first pixel electrode ELT1′ may be surrounded by the second portion of the first pixel electrode ELT1′ and the third portion of the first pixel electrode ELT1′.

In an embodiment, the second pixel PXL2 may include the first pixel electrode ELT1. In another example, the second pixel PXL2 may include the first pixel electrode ELT1′.

Referring to FIGS. 5A and 5C, at least a first pixel electrode ELT1″ of the first pixel PXL1 and a second pixel electrode ELT2″ of the second pixel PXL2 may be distinguishable from those shown in FIG. 5A. Therefore, the same reference numerals are used for the same or corresponding components, and duplicate descriptions will be omitted.

The first pixel PXL1 may include the first pixel electrode ELT1″, and the second pixel PXL2 may include the second pixel electrode ELT2″.

The first pixel electrode ELT1″ of the first pixel PXL1 may include a first portion of a bar shape having a constant width and a second portion having a protrusion protruding in a direction from the bar shape. The bar shape of the pixel electrode ELT1″ may extend from the first emission area EMA1 to the non-emission area NEA. The shape of the first pixel electrode ELT1″ having the protrusion may be provided in the non-emission area NEA.

In an embodiment, the first pixel electrode ELT1″ may extend from the first emission area EMA1 to the non-emission area NEA, and may include the first portion disposed on the first dummy electrode ALE1a and including the first contact hole CH1 and the second portion extending from the first portion and overlapping at least one region of the second dummy electrode ALE2a of the first pixel PXL1.

In an embodiment, the second pixel electrode ELT2″ of the second pixel PXL2 may include a bar shape having a constant width and a protrusion protruding in a direction from the bar shape. The bar shape of the second pixel electrode ELT2″ may extend from the second emission area EMA2 to the non-emission area NEA (or the non-emission area NEA between the first and second emission areas EMA1 and EMA2). The shape of the second pixel electrode ELT2″ having the protrusion may be provided in the non-emission area NEA.

In an embodiment, the second pixel electrode ELT2″ may extend from the second emission area EMA2 to the non-emission area NEA, and may include a first portion disposed on the first dummy electrode ALE1b, and a second portion extending from the first portion and overlapping at least one region of the second dummy electrode ALE2a of the first pixel PXL1.

In an embodiment, the first pixel electrode ELT1″ of the first pixel PXL1 may be disposed to be spaced apart from the second portion of the second pixel electrode ELT2″ of the second pixel PXL2 in the second direction DR2. The second portion of the first pixel electrode ELT1″ of the first pixel PXL1 and the second portion of the second pixel electrode ELT2″ of the second pixel PXL2 may overlap the second dummy electrode ALE2a of the first pixel PXL1.

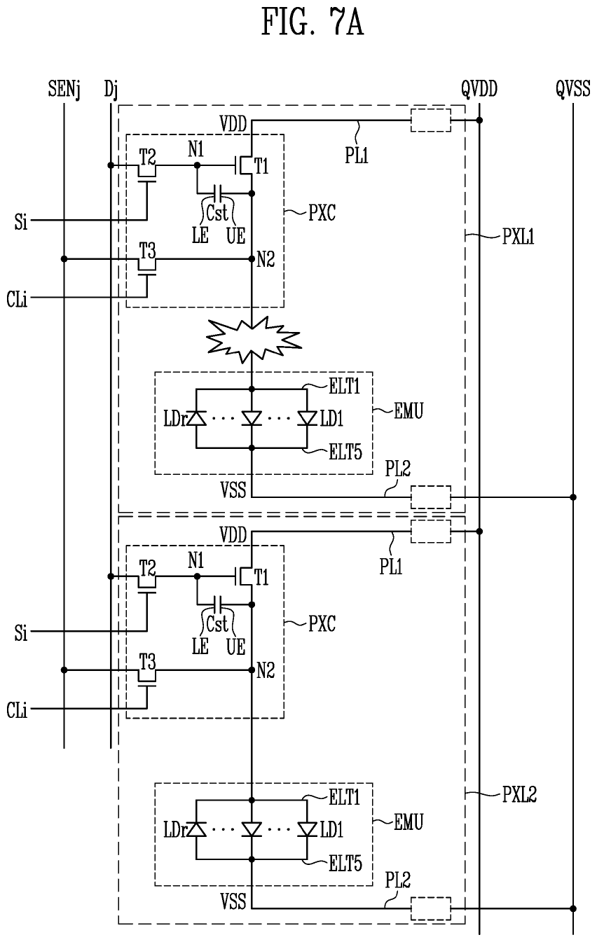

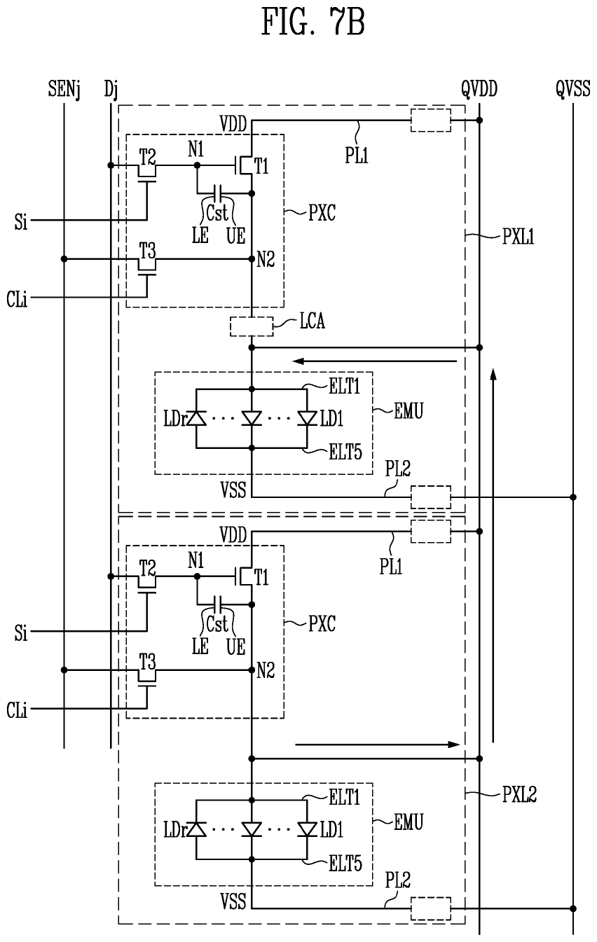

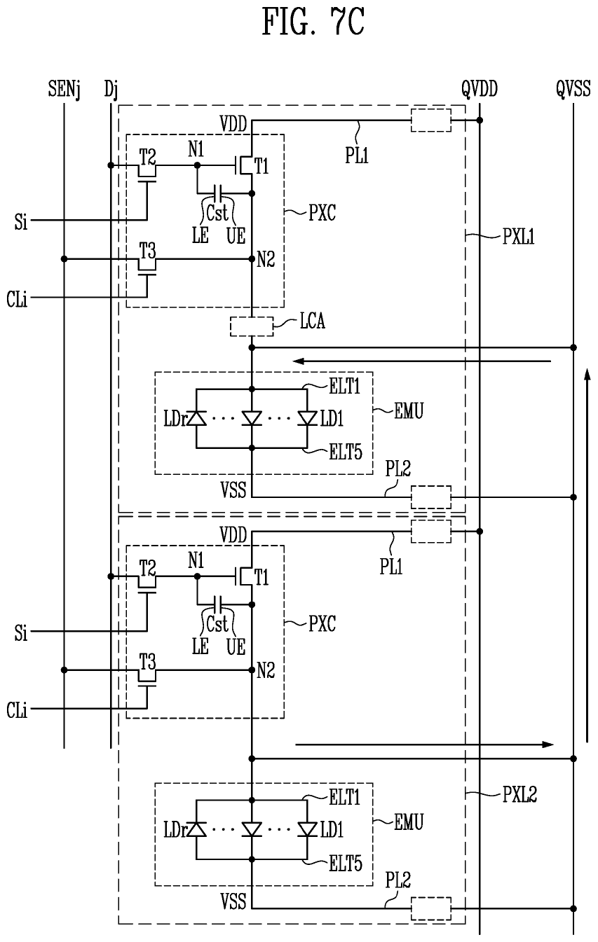

The plan views of the pixel shown in FIGS. 5A to 5C may illustrate the pixel PXL in a normal state, but the disclosure is not limited thereto. For example, the pixel shown in FIGS. 5A to 5C may be the pixel PXL before a repair process is performed for the pixel PXL in a defective state (refer to FIG. 7A).

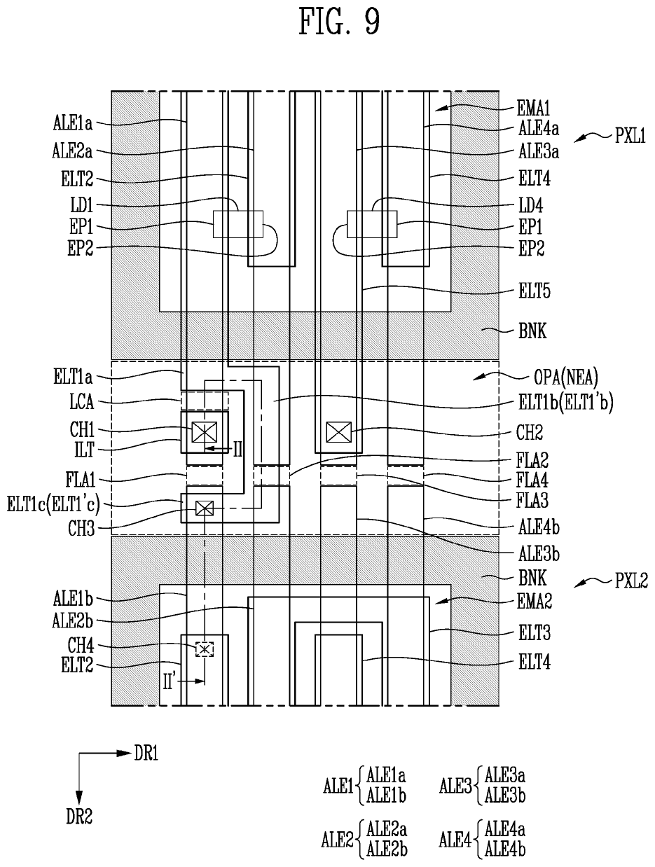

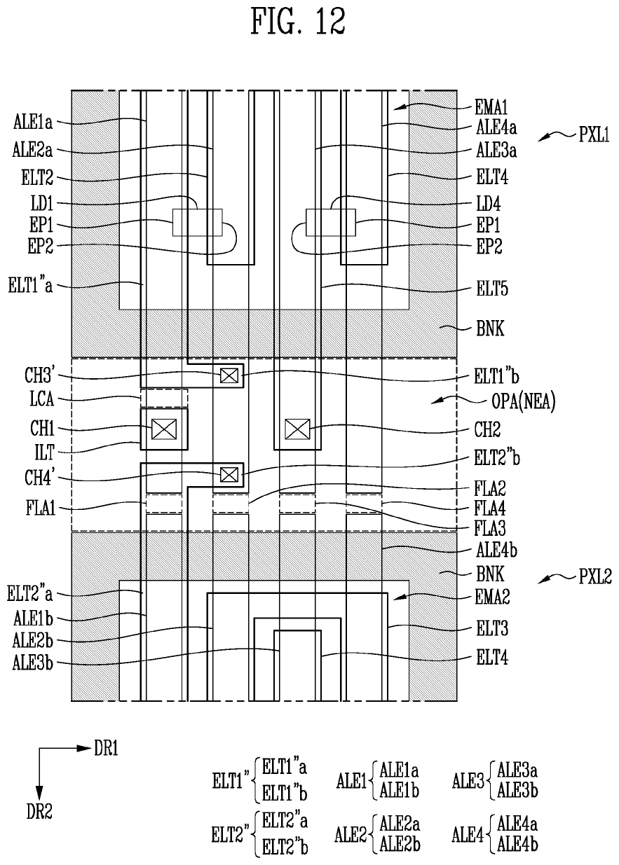

In case that the light emitting state of the light emitting elements LD of the first pixel PXL1 is defective due to a defect in the pixel circuit PXC of the first pixel PXL1 in a process of manufacturing the first pixel PXL1, each of the first pixel electrode ELT1′ of FIG. 5B and the first pixel electrode ELT1″ of FIG. 5C may be a pixel electrode processed for convenience in the repair process for the first pixel PXL1 in a defective state. In an example, the repair process may be performed on the third portion of the first pixel electrode ELT1′ (for example, the third portion ELT1′c of FIG. 9) and the second portion of the first pixel electrode ELT1″ (for example, the second portion ELT1″b of FIG. 12).

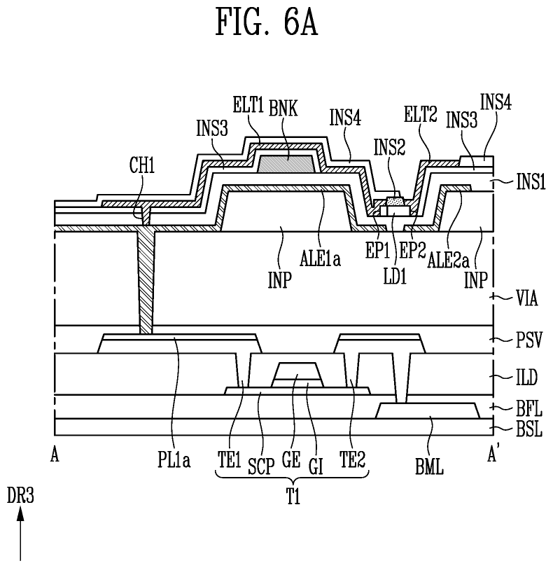

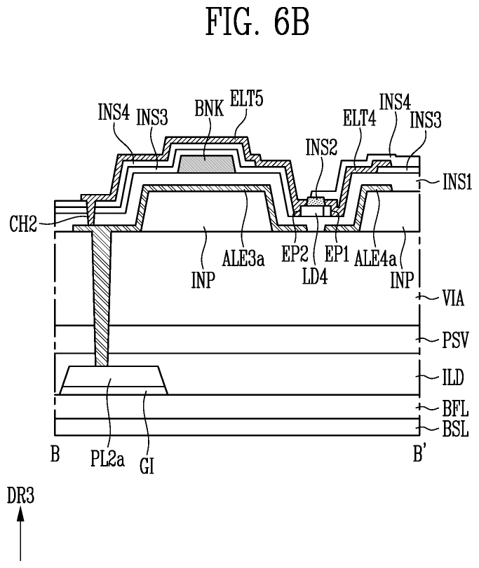

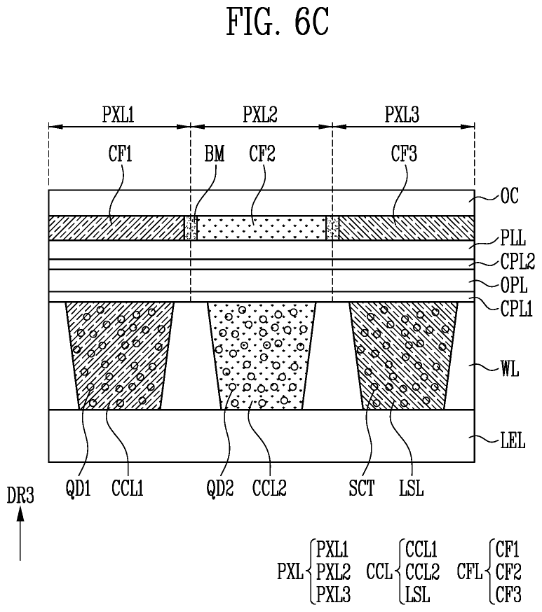

FIG. 6A is a cross-sectional view schematically illustrating an example of a cross section taken along line A-A′ of FIG. 5A. FIG. 6B is a cross-sectional view schematically illustrating an example of a cross section taken along line B-B′ of FIG. 5A.

Hereinafter, a cross-sectional structure of the first pixel PXL1 will be described in detail with reference to FIGS. 6A and 6B, focusing on the first light emitting element LD1. FIGS. 6A and 6B illustrate the first transistor T1 as an example among various circuit elements constituting the pixel circuit (for example, the pixel circuit PXC of FIG. 4). In case that it is not necessary to separately refer to the first to third transistors T1 to T3, they will be collectively referred to as “transistor T”. The structure and/or position of each layer of the transistors T is not limited to the embodiment shown in FIG. 6A and may be variously changed depending on embodiments.

Referring to FIGS. 5A, 6A, and 6B, a circuit element layer of the first pixel PXL1 may include circuit elements including transistors T disposed on a base layer BSL and various wirings electrically connected thereto. The dummy electrodes ALE1a to ALE4a, the light emitting elements LD1 to LD4, and/or the pixel electrodes ELT1 to ELT5 constituting the emission part EMU may be disposed on the circuit elements. A light emitting element layer may be disposed on the circuit element layer. The light emitting element layer may include the light emitting elements LD.

In an embodiment, the base layer BSL may constitute a base member and may be a rigid or flexible substrate or film. As an example, the base layer BSL may be a rigid substrate made of glass or tempered glass, a flexible substrate (or thin film) made of plastic or metal, or at least one insulating layer. The material and/or physical properties of the base layer BSL are not particularly limited. In an embodiment, the base layer BSL may be substantially transparent. The expression “substantially transparent” may mean that light can be transmitted with a transmittance (e.g., a predetermined or selectable transmittance) or higher. In another embodiment, the base layer BSL may be translucent or opaque. The base layer BSL may include a reflective material according to embodiments.

In an embodiment, a buffer layer BFL may be disposed on the base layer BSL. The buffer layer BFL may prevent impurities from diffusing into the circuit elements. The buffer layer BFL may be composed of a single layer, but may also be composed of multiple layers including at least a double layer. In case that the buffer layer BFL is formed as multiple layers, each layer may be formed of a same material or different materials.

The buffer layer BFL may be an inorganic insulating layer including an inorganic material. In an example, the buffer layer BFL may include at least one of silicon nitride (SiNx), silicon oxide (SiOx), silicon oxynitride (SiOxNy), and a metal oxide such as aluminum oxide (AlOx). The buffer layer BFL may be provided as a single layer, but may also be provided as multiple layers including a double layer.

A semiconductor pattern SCP may be disposed on the buffer layer BFL. The semiconductor pattern SCP may include a first region contacting a first transistor electrode TE1, a second region contacting a second transistor electrode TE2, and a channel region positioned between the first and second regions. According to an embodiment, one of the first and second regions may be a source region, and the other may be a drain region. In an embodiment, the first transistor electrode TE1 may be electrically connected to a first power source conductive layer PL1a.

In an embodiment, the semiconductor pattern SCP may be formed of polysilicon, amorphous silicon, an oxide semiconductor, or the like. The channel region of the semiconductor pattern SCP may be a semiconductor pattern not doped with impurities and may be an intrinsic semiconductor. The first and second regions of the semiconductor pattern SCP may be semiconductors doped with impurities.

Referring to FIGS. 6A and 6B, a gate insulating layer GI may be disposed on the buffer layer BFL and the semiconductor pattern SCP. As an example, the gate insulating layer GI may be disposed between the semiconductor pattern SCP and a gate electrode GE. The gate insulating layer GI may be disposed between the buffer layer BFL and a second power source conductive layer PL2a. The gate insulating layer GI may be composed of a single layer or multiple layers, and may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The gate electrode GE of the transistor T and the second power source conductive layer PL2a may be disposed on the gate insulating layer GI. The gate electrode GE and the second power source conductive layer PL2a may be disposed on a same layer. For example, the gate electrode GE and the second power source conductive layer PL2a may be simultaneously formed in a same process, but the disclosure is not limited thereto. The gate electrode GE may be disposed on the gate insulating layer GI to overlap the semiconductor pattern SCP in the third direction DR3. The second power source conductive layer PL2a may constitute the second power source line PL2 described with reference to FIG. 4 and the like.

Each of the gate electrode GE and the second power source conductive layer PL2a may be formed as a single layer or multiple layers including molybdenum (Mo), copper (Cu), aluminum (Al), chromium (Cr), gold (Au), titanium (Ti), nickel (Ni), neodymium (Nd), indium (In), tin (Sn), or an oxide or alloy thereof. For example, each of the gate electrode GE and the second power source conductive layer PL2a may be formed as multiple layers in which titanium (Ti), copper (Cu), and/or indium tin oxide (ITO) are sequentially or repeatedly stacked.

An interlayer insulating layer ILD may be disposed on the gate electrode GE and the second power source conductive layer PL2a. As an example, the interlayer insulating layer ILD may be disposed between the gate electrode GE and the first and second transistor electrodes TE1 and TE2. The interlayer insulating layer ILD and the gate insulating layer GI may include a same material, or the interlayer insulating layer ILD may include one or more materials selected from materials constituting the gate insulating layer GI.

Referring to FIG. 6A, the first and second transistor electrodes TE1 and TE2 may be disposed to overlap the semiconductor pattern SCP in the third direction DR3. The first and second transistor electrodes TE1 and TE2 may be electrically connected to the semiconductor pattern SCP. For example, the first transistor electrode TE1 may be electrically connected to the first region of the semiconductor pattern SCP through a contact hole penetrating the interlayer insulating layer ILD. The second transistor electrode TE2 may be electrically connected to the second region of the semiconductor pattern SCP through a contact hole penetrating the interlayer insulating layer ILD. The second transistor electrode TE2 may be electrically connected to a conductive layer BML receiving the first driving power source VDD. According to an embodiment, one of the first and second transistor electrodes TE1 and TE2 may be a source electrode, and the other may be a drain electrode.

In an embodiment, the first and second transistor electrodes TE1 and TE2 (and the first power source conductive layer PL1a) may be formed as a single layer or multiple layers including molybdenum (Mo), copper (Cu), aluminum (Al), chromium (Cr), gold (Au), titanium (Ti), nickel (Ni), neodymium (Nd), indium (In), tin (Sn), or an oxide or alloy thereof.

A passivation layer PSV may be disposed on the first and second transistor electrodes TE1 and TE2 and the second power source conductive layer PL2a. The passivation layer PSV may be composed of a single layer or multiple layers, and may include an inorganic material such as silicon oxide (SiOx).

In an embodiment, a via layer VIA may be disposed on the passivation layer PSV. The via layer VIA may be made of an organic material to reduce a lower step difference. For example, the via layer VIA may include various types of inorganic materials.

In an embodiment, bank patterns INP may be disposed on the via layer VIA. The bank patterns INP may have various shapes according to embodiments. In an embodiment, the bank patterns INP may have a shape protruding in the third direction DR3 on the base layer BSL. The bank patterns INP may be formed to have an inclined surface inclined at an angle (e.g., a predetermined or selectable angle) with respect to the base layer BSL. However, the disclosure is not limited thereto, and the bank patterns INP may have curved or stepped sidewalls. As an example, the bank patterns INP may have a semicircular or semielliptical cross section.

The dummy electrodes ALE1a to ALE4a may be disposed on the via layer VIA and the bank patterns INP. The dummy electrodes ALE1a to ALE4a may be disposed to be spaced apart from each other in the first pixel PXL1. The dummy electrodes ALE1a to ALE4a may be disposed on a same layer. For example, the dummy electrodes ALE1a to ALE4a may be simultaneously formed in a same process, but the disclosure is not limited thereto.

In an embodiment, the dummy electrodes ALE1a to ALE4a disposed on the bank patterns INP may have a cross-sectional shape corresponding to that of the bank patterns INP. As an example, the dummy electrodes ALE1a to ALE4a disposed on the bank patterns INP may include inclined surfaces or curved surfaces having shapes corresponding to the shapes of the bank patterns INP. Accordingly, the bank patterns INP, together with the dummy electrodes ALE1a to ALE4a provided thereon, may function as reflective members that improve light output efficiency of the display device by guiding light emitted from the light emitting elements LD in the front direction of the first pixel PXL1, for example, in the third direction DR3.

The dummy electrodes ALE1a to ALE4a may receive alignment signals in a step of aligning the light emitting elements LD. Accordingly, an electric field may be formed between the dummy electrodes ALE1a to ALE4a so that the light emitting elements LD provided in the first pixel PXL1 may be aligned between the dummy electrodes ALE1a to ALE4a.

The dummy electrodes ALE1a to ALE4a may include at least one conductive material. As an example, the electrodes ALE may include various metal materials such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu). Since the dummy electrodes ALE1a to ALE4a may correspond to reflective electrodes, they may include a metal (or metal material) having a specific reflectance. The dummy electrodes ALE1a to ALE4a may include at least one of the metal or an alloy including the same. The dummy electrodes ALE1a to ALE4a may include at least one conductive material of a conductive oxide such as indium tin oxide (ITO), indium zinc oxide (IZO), indium tin zinc oxide (ITZO), aluminum zinc oxide (AZO), gallium zinc oxide (GZO), zinc tin oxide. (ZTO), or gallium tin oxide (GTO), and a conductive polymer such as poly(3,4-ethylenedioxythiophene) (PEDOT), but the disclosure is not limited thereto. The at least one conductive material may be a material for protecting the metal.

In an embodiment, the first dummy electrode ALE1a may be electrically connected to the first transistor electrode TE1 of the transistor T through a contact hole penetrating the via layer VIA and the passivation layer PSV. The third dummy electrode ALE3a may be electrically connected to the second power source conductive layer PL2a through a contact hole penetrating the via layer VIA, the passivation layer PSV, and the interlayer insulating layer ILD.

A first insulating layer INS1 may be disposed on the dummy electrodes ALE1a to ALE4a. The first insulating layer INS1 may be composed of a single layer or multiple layers, and may include various types of inorganic materials.

The bank BNK may be disposed on the first insulating layer INS1. In a step of supplying the light emitting elements LD to the first pixel PXL1, the bank BNK may be a dam structure that partitions an emission area to which the light emitting elements LD are to be supplied. A desired type and/or amount of light emitting element ink may be supplied to the emission area partitioned by the bank BNK.

According to an embodiment, the bank BNK may include at least one light blocking and/or reflective material. Accordingly, light leakage between adjacent pixels PXL may be prevented. For example, the bank BNK may include at least one black matrix material and/or color filter material. As an example, the bank BNK may be formed in a black opaque pattern capable of blocking transmission of light. In an embodiment, a reflective film or the like may be formed on a surface (for example, a sidewall) of the bank BNK to increase light efficiency of each pixel PXL.

The light emitting elements LD may be disposed on the first insulating layer INS1. The light emitting elements LD may be disposed between the first dummy electrode ALE1a and the second dummy electrode ALE2a and between the third dummy electrode ALE3a and the fourth dummy electrode ALE4a on the first insulating layer INS1. The light emitting elements LD may be prepared to be dispersed in the light emitting element ink and may be supplied to each pixel PXL through an inkjet printing method or the like. For example, the light emitting elements LD may be provided to each pixel PXL by being dispersed in a volatile solvent.

A second insulating layer INS2 may be disposed on the light emitting elements LD. For example, the second insulating layer INS2 may be partially provided on the light emitting elements LD and may expose the first and second ends EP1 and EP2 of the light emitting elements LD. In case that the second insulating layer INS2 is formed on the light emitting elements LD after the light emitting elements LD are aligned, the light emitting elements LD may be prevented from being separated from the aligned positions.

A third insulating layer INS3 may be disposed on at least a portion of the first insulating layer INS1 and the bank BNK.

The pixel electrodes (for example, the pixel electrodes ELT1, ELT2, ELT4, and ELT5) may be formed on the first and second ends EP1 and EP2 of the light emitting elements LD exposed by the second insulating layer INS2 and the third insulating layer INS3. In an embodiment, the first pixel electrode ELT1 may be electrically connected to the first dummy electrode ALE1a through the first contact hole CH1, and the fifth pixel electrode ELT5 may be electrically connected to the third dummy electrode ALE3a through the second contact hole CH2. Since the first dummy electrode ALE1a may be electrically connected to the first power source conductive layer PL1a, the first pixel electrode ELT1 may be electrically connected to the first power source conductive layer PL1a through the first dummy electrode ALE1a. Since the third dummy electrode ALE3a may be electrically connected to the second power source conductive layer PL2a, the fifth pixel electrode ELT5 may be electrically connected to the second power source conductive layer PL2a through the second contact hole CH2.

In an embodiment, the first pixel electrode ELT1 may be directly disposed on the first ends EP1 of the first light emitting elements LD1 and may contact the first ends EP1 of the first light emitting elements LD1. The second pixel electrode ELT2 may be directly disposed on the second ends EP2 of the first light emitting elements LD1 and may contact the second ends EP2 of the first light emitting elements LD1. In an embodiment, the fourth pixel electrode ELT4 may be directly disposed on the first ends EP1 of the fourth light emitting elements LD4 and may contact the first ends EP1 of the fourth light emitting elements LD4. The fifth pixel electrode ELT5 may be directly disposed on the second ends EP2 of the fourth light emitting elements LD4 and may contact the second ends EP2 of the fourth light emitting elements LD4.

In case that a fourth insulating layer INS4 is disposed between the pixel electrodes ELT1, ELT2, ELT4, and ELT5, the pixel electrodes ELT1, ELT2, ELT4, and ELT5 may be stably separated from each other by the fourth insulating layer INS4. For example, the first pixel electrode ELT1 and the second pixel electrode ELT2 may be disposed on different layers with the fourth insulating layer INS4 interposed therebetween. Thus, electrical stability between the first and second ends EP1 and EP2 of the light emitting elements LD can be secured.

In an embodiment, the fourth insulating layer INS4 may be disposed to cover at least some regions of the first pixel electrode ELT1, the fourth pixel electrode ELT4, the second insulating layer INS2, and the third insulating layer INS3.

The third insulating layer INS3 and the fourth insulating layer INS4 may be composed of a single layer or multiple layers and may include various types of inorganic materials.

FIG. 6C is a schematic cross-sectional view illustrating first to third pixels included in the display device of FIG. 3.

FIG. 6C illustrates a barrier wall WL, a color conversion layer CCL, an optical layer OPL, and/or a color filter layer CFL provided on a light emitting element layer LEL of the pixel PXL of FIG. 3.

Referring to FIG. 6C, the barrier wall WL may be disposed on the light emitting element layer LEL of the first to third pixels PXL1 to PXL3. As an example, the barrier wall WL may be disposed between or at a boundary between the first to third pixels PXL1 to PXL3, and may include openings overlapping the first to third pixels PXL1 to PXL3, respectively. The openings of the barrier wall WL may provide a space in which the color conversion layer CCL is provided.

The barrier wall WL may include an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not limited thereto, and the barrier wall WL may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

According to an embodiment, the barrier wall WL may include at least one light blocking and/or reflective material. Accordingly, light leakage between adjacent pixels PXL may be prevented. For example, the barrier wall WL may include at least one black matrix material and/or color filter material. As an example, the barrier wall WL may be formed in a black opaque pattern capable of blocking transmission of light. In an embodiment, a reflective film (not shown) or the like may be formed on a surface (for example, a sidewall) of the barrier wall WL to increase light efficiency of each pixel PXL.

The color conversion layer CCL may be disposed on the light emitting element layer LEL including the light emitting elements LD in the opening of the barrier wall WL. The color conversion layer CCL may include a first color conversion layer CCL1 disposed in the first pixel PXL1, a second color conversion layer CCL2 disposed in the second pixel PXL2, and a scattering layer LSL disposed in the third pixel PXL3.

In an embodiment, the first to third pixels PXL1, PXL2, and PXL3 may include light emitting elements LD emitting light of a same color. For example, the first to third pixels PXL1, PXL2, and PXL3 may include light emitting elements LD emitting light of a third color (or blue). A full-color image may be displayed by disposing the color conversion layer CCL including color conversion particles on the first to third pixels PXL1, PXL2, and PXL3, respectively.

The first color conversion layer CCL1 may include first color conversion particles that convert light of the third color emitted from the light emitting element LD into light of a first color. For example, the first color conversion layer CCL1 may include first quantum dots QD1 dispersed in a matrix material such as a base resin.

In an embodiment, in case that the light emitting element LD is a blue light emitting element emitting blue light and the first pixel PXL1 is a red pixel, the first color conversion layer CCL1 may include the first quantum dots QD1 that convert the blue light emitted from the blue light emitting element into red light. The first quantum dots QD1 may absorb blue light and emit red light by shifting the wavelength according to an energy transition. In case that the first pixel PXL1 is a pixel of a different color, the first color conversion layer CCL1 may include the first quantum dots QD1 corresponding to the color of the first pixel PXL1.

The second color conversion layer CCL2 may include second color conversion particles that convert light of the third color emitted from the light emitting element LD into light of a second color. For example, the second color conversion layer CCL2 may include second quantum dots QD2 dispersed in a matrix material such as a base resin.

In an embodiment, in case that the light emitting element LD is a blue light emitting element emitting blue light and the second pixel PXL2 is a green pixel, the second color conversion layer CCL2 may include the second quantum dots QD2 that convert the blue light emitted from the blue light emitting element into green light. The second quantum dots QD2 may absorb blue light and emit green light by shifting the wavelength according to an energy transition. In case that the second pixel PXL2 is a pixel of a different color, the second color conversion layer CCL2 may include the second quantum dots QD2 corresponding to the color of the second pixel PXL2.

In an embodiment, as blue light having a relatively short wavelength in the visible light region is incident to the first quantum dots QD1 and the second quantum dots QD2, absorption coefficients of the first quantum dots QD1 and the second quantum dots QD2 may be increased. Accordingly, efficiency of light finally emitted from the first pixel PXL1 and the second pixel PXL2 may be improved, and excellent color reproducibility can be secured. Manufacturing efficiency of the display device can be increased by configuring the emission part EMU (refer to FIG. 4) (or the light emitting element layer LEL) of the first to third pixels PXL1, PXL2, and PXL3 using the light emitting elements LD of a same color (for example, blue light emitting elements).

The scattering layer LSL may be provided to efficiently use light of the third color (or blue) emitted from the light emitting element LD. As an example, in case that the light emitting element LD is a blue light emitting element emitting blue light and the third pixel PXL3 is a blue pixel, the scattering layer LSL may include at least one type of scatterers SCT in order to efficiently use the light emitted from the light emitting element LD.

For example, the scattering layer LSL may include scatterers SCT dispersed in a matrix material such as a base resin. As an example, the scattering layer LSL may include the scatterers SCT such as silica, but the material constituting the scatterers SCT is not limited thereto. The scatterers SCT are not disposed only in the third pixel PXL3, and may be selectively included in the first color conversion layer CCL1 or the second color conversion layer CCL2. According to an embodiment, the scattering layer LSL composed of a transparent polymer may be provided by omitting the scatterers SCT.

A first capping layer CPL1 may be disposed on the color conversion layer CCL. The first capping layer CPL1 may be provided over the first to third pixels PXL1 to PXL3. The first capping layer CPL1 may cover the color conversion layer CCL. The first capping layer CPL1 may prevent impurities such as moisture or air from penetrating from outside to damage or contaminate the color conversion layer CCL.

The first capping layer CPL1 may be an inorganic layer, and may include silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

The optical layer OPL may be disposed on the first capping layer CPL1. The optical layer OPL may serve to improve light extraction efficiency by recycling light provided from the color conversion layer CCL through total reflection. To this end, the optical layer OPL may have a relatively low refractive index compared to the color conversion layer CCL. For example, the refractive index of the color conversion layer CCL may be about 1.6 to about 2.0, and the refractive index of the optical layer OPL may be about 1.1 to about 1.3.

A second capping layer CPL2 may be disposed on the optical layer OPL. The second capping layer CPL2 may be provided over the first to third pixels PXL1, PXL2, and PXL3. The second capping layer CPL2 may cover the optical layer OPL. The second capping layer CPL2 may prevent impurity such as moisture or air from damaging or contaminating the optical layer OPL by penetrating therethrough from the outside.

The second capping layer CPL2 may be an inorganic layer, and may include silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

A planarization layer PLL may be disposed on the second capping layer CPL2. The planarization layer PLL may be provided over the first to third pixels PXL1, PXL2, and PXL3.

The planarization layer PLL may include an organic material such as an acrylic resin, an epoxy resin, a phenolic resin, a polyamide resin, a polyimide resin, a polyester resin, a polyphenylenesulfide resin, benzocyclobutene (BCB), or the like. However, the disclosure is not limited thereto, and the planarization layer PLL may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The color filter layer CFL may be disposed on the planarization layer PLL. The color filter layer CFL may include color filters CF1, CF2, and CF3 corresponding to the color of each pixel PXL. A full-color image may be displayed by arranging the color filters CF1, CF2, and CF3 corresponding to the color of each of the first to third pixels PXL1, PXL2, and PXL3.

The color filter layer CFL may include a first color filter CF1 disposed in the first pixel PXL1 to selectively transmit light emitted from the first pixel PXL1, a second color filter CF2 disposed in the second pixel PXL2 to selectively transmit light emitted from the second pixel PXL2, and a third color filter CF3 disposed in the third pixel PXL3 to selectively transmit light emitted from the third pixel PXL3.

In an embodiment, the first color filter CF1, the second color filter CF2, and the third color filter CF3 may be a red color filter, a green color filter, and a blue color filter, respectively, but the disclosure is not limited thereto. Hereinafter, in case that any color filter among the first color filter CF1, the second color filter CF2, and the third color filter CF3 is arbitrarily referred to, or two or more types of color filters are comprehensively referred to, they will be referred to as “color filter CF” or “color filters CF”.

The first color filter CF1 may overlap the light emitting element layer LEL (or the light emitting element LD) and the first color conversion layer CCL1 of the first pixel PXL1 in the third direction DR3. The first color filter CF1 may include a color filter material that selectively transmits light of the first color (or red). For example, in case that the first pixel PXL1 is a red pixel, the first color filter CF1 may include a red color filter material.

The second color filter CF2 may overlap the light emitting element layer LEL (or the light emitting element LD) and the second color conversion layer CCL2 of the second pixel PXL2 in the third direction DR3. The second color filter CF2 may include a color filter material that selectively transmits light of the second color (or green). For example, in case that the second pixel PXL2 is a green pixel, the second color filter CF2 may include a green color filter material.

The third color filter CF3 may overlap the light emitting element layer LEL (or the light emitting element LD) and the scattering layer LSL of the third pixel PXL3 in the third direction DR3. The third color filter CF3 may include a color filter material that selectively transmits light of the third color (or blue). For example, in case that the third pixel PXL3 is a blue pixel, the third color filter CF3 may include a blue color filter material.

According to an embodiment, a light blocking layer BM may be further disposed between the first to third color filters CF1, CF2, and CF3. Thus, in case that the light blocking layer BM is formed between the first to third color filters CF1, CF2, and CF3, color mixing defects visually recognized from the front or side of the display device can be prevented. The material of the light blocking layer BM is not particularly limited and may be composed of various light blocking materials. As an example, the light blocking layer BM may be implemented by stacking the first to third color filters CF1, CF2, and CF3 on each other.

An overcoat layer OC may be disposed on the color filter layer CFL. The overcoat layer OC may be provided over the first to third pixels PXL1, PXL2, and PXL3. The overcoat layer OC may cover lower members including the color filter layer CFL. The overcoat layer OC may prevent penetration of moisture or air into the lower members. The overcoat layer OC may protect the lower members from foreign substances such as dust.

The overcoat layer OC may include an organic material such as an acrylic resin, an epoxy resin, a phenolic resin, a polyamide resin, a polyimide resin, a polyester resin, a polyphenylenesulfide resin, benzocyclobutene (BCB), or the like. However, the disclosure is not limited thereto, and the overcoat layer OC may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

FIG. 7A is a schematic diagram of an equivalent circuit illustrating an example of the pixel included in the display device of FIG. 3 in case that the pixel is in a defective state.

FIG. 7A schematically illustrates a case in which the first pixel PXL1 is in a defective state. For example, FIG. 7A illustrates a state in which the emission part EMU is not electrically connected to the pixel circuit PXC through the second node N2 due to a defect in the pixel circuit PXC of the pixel PXL shown in FIG. 4. In case that the pixel PXL is in a defective state, the light emitting elements LD included in a corresponding pixel may not emit light.

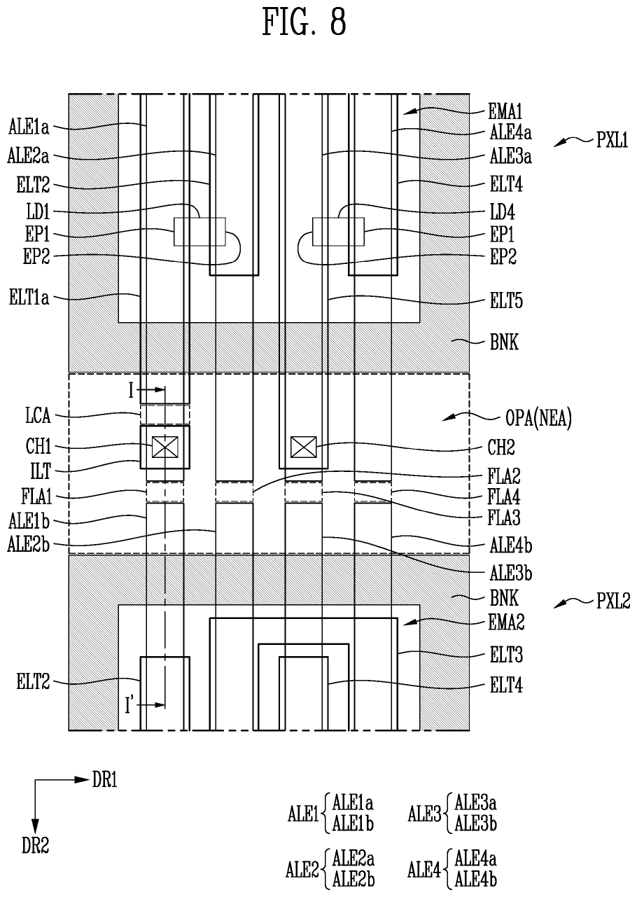

In an embodiment, an inspection to determine whether the pixel PXL is defective may be performed in a process of manufacturing the pixel PXL. For example, after disposing the alignment electrodes (for example, the alignment electrodes ALE1 to ALE4 of FIG. 8), providing the light emitting elements LD to the emission area (for example, the first and second emission areas EMA1 and EMA2 of FIG. 8), aligning the light emitting elements LD by an electric field formed through the alignment electrodes ALE1 to ALE4, and/or disposing the pixel electrodes ELT1 to ELT5 on the light emitting elements LD, the inspection to determine whether the pixel PXL is defective may be performed through a mother substrate inspection device. The mother substrate inspection device may be a device capable of determining whether a pixel circuit PXC of a mother panel is defective. In an example, the inspection to determine whether the pixel PXL is defective may be performed after disposing the pixel electrodes ELT1 to ELT5 on the light emitting elements LD, and removing at least a portion of at least one of the alignment electrodes ALE1 to ALE4 (for example, a separation process). In the disclosure, the inspection to determine whether the pixel PXL normally emits light (or turns on) will be referred to as a lighting inspection.

In an embodiment, in the inspection to determine whether the pixel PXL is defective, in case that the first pixel PXL1 is in a defective state and the second pixel PXL2 adjacent thereto is in a normal state, the repair process for the first pixel PXL1 may be performed.

Hereinafter, a repair method for a pixel in a defective state will be described with reference to FIGS. 7B to 13.

FIGS. 7B and 7C are schematic diagrams of equivalent circuits illustrating an example of the pixel for explaining a repair method for the pixel in a defective state of FIG. 7A.

Referring to FIGS. 7B and 7C, in case that the first pixel PXL1 is in a defective state and the second pixel PXL2 (or the second pixel PXL2 adjacent to the first pixel PXL1) is in a normal state, the repair method may include disconnecting a connection between the emission part EMU and the pixel circuit PXC in the first pixel PXL1, and electrically connecting anode electrodes of the first pixel PXL1 and the second pixel PXL2 to each other by using one (for example, the first to fourth dummy electrodes ALE1a to ALE4a and ALE1b to ALE4b of FIG. 5A) of the dummy electrodes (for example, the first to fourth dummy electrodes ALE1a to ALE4a and ALE1b to ALE4b of FIG. 8).

Referring to FIG. 7B, by using a dummy electrode of which a portion is removed and which is in a floating state among the dummy electrodes ALE1a to ALE4a and ALE1b to ALE4b after receiving a first alignment signal QVDD, the anode electrode of the second pixel PXL2 may be electrically connected to the anode electrode of the first pixel PXL1.

Referring to FIG. 7C, by using a dummy electrode of which a portion is removed and which is in a floating state among the dummy electrodes ALE1a to ALE4a and ALE1b to ALE4b after receiving a second alignment signal QVSS, the anode electrode of the second pixel PXL2 may be electrically connected to the anode electrode of the first pixel PXL1.

FIGS. 8 and 9 are schematic plan views illustrating an example of the pixel for explaining the repair method for the pixel in a defective state of FIG. 7A.

Referring to FIGS. 7A, 8, and 9, in case that the first pixel PXL1 is in a defective state and the second pixel PXL2 adjacent thereto is in a normal state, the repair process for the first pixel PXL1 may be performed in the opening area OPA, which is the non-emission area NEA. The repair process for the first pixel PXL1 may include a process for cutting a portion of the first pixel electrode ELT1 of the first pixel PXL1 to disconnect a connection between the first pixel electrode ELT1 and the pixel circuit PXC and a process of electrically connecting the first pixel electrode ELT1 of the first pixel PXL1 to the anode electrode of the second pixel PXL2 adjacent thereto.

Referring to FIG. 8, a process for disconnecting the connection between the first pixel electrode ELT1 of the first pixel PXL1 and the pixel circuit PXC may be performed in the non-emission area NEA.

In an embodiment, a portion of the first pixel electrode ELT1 of the first pixel PXL1 may be removed in the non-emission area NEA. In an example, the first pixel electrode ELT1 may be removed by irradiating or emitting laser light to a cutting area LCA located in an area adjacent to the first contact hole CH1.

In an embodiment, the first pixel electrode ELT1 may be separated into a first partial electrode ELT1a and an isolated electrode ILT by removing the cutting area LCA of the first pixel electrode ELT1. The isolated electrode ILT may be disposed to be spaced apart from the first partial electrode ELT1a in the second direction DR2 and may not be electrically connected to the first partial electrode ELT1a.

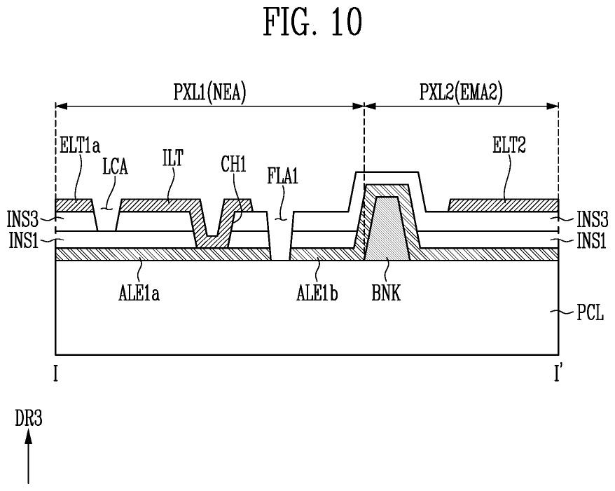

In an embodiment, the isolated electrode ILT may include the first contact hole CH1. In an example, the isolated electrode ILT may be electrically connected to the first dummy electrode ALE1a through the first contact hole CH1. The first dummy electrode ALE1a may contact the pixel circuit PXC disposed in the pixel circuit layer (for example, the pixel circuit layer PCL of FIG. 10) disposed under the first dummy electrode ALE1a.

In an embodiment, the first partial electrode ELT1a may contact the first ends EP1 of the first light emitting elements LD1 in the first emission area EMA1. At least a portion of the first partial electrode ELT1a may extend from the first emission area EMA1 to the non-emission area NEA. The first partial electrode ELT1a may be in a floating state as it is not electrically connected to the isolated electrode ILT.

FIG. 9 illustrates a process of electrically connecting the first partial electrode ELT1a and ELT1′a and the second pixel electrode ELT2 of the second pixel PXL2 adjacent thereto after the process for disconnecting the connection between the first pixel electrode ELT1 and ELT1′ of the first pixel PXL1 and the pixel circuit PXC is performed.

Referring to FIG. 9, the first partial electrode ELT1a may extend from the first emission area EMA1 to the non-emission area NEA, and may be integral with a second partial electrode ELT1b and a third partial electrode ELT1c. The third partial electrode ELT1c may have a shape having a bent portion overlapping the first dummy electrode ALE1b of the second pixel PXL2. The second partial electrode ELT1b may be an electrode electrically connecting the first partial electrode ELT1a and the third partial electrode ELT1c. For example, the second partial electrode ELT1b may be formed to bypass the isolated electrode ILT. In an example, the second partial electrode ELT1b may protrude from the first partial electrode ELT1a in the first direction DR1 and overlap the second dummy electrode ALE2a. However, the disclosure is not limited thereto, and the second partial electrode ELT1b may protrude in a direction opposite to the first direction DR1.

In an embodiment, after the first pixel electrode (for example, the first pixel electrode ELT1 of FIG. 5A) is separated into the first partial electrode ELT1a and the isolated electrode ILT, the second partial electrode ELT1b and the third partial electrode ELT1c may be integral with the first partial electrode ELT1a. For example, a process of forming the second partial electrode ELT1b and the third partial electrode ELT1c may be performed so that the first partial electrode ELT1a is electrically connected to the second partial electrode ELT1b and the third partial electrode ELT1c.

In an embodiment, the second partial electrode ELT1b and the third partial electrode ELT1c may be repair electrodes formed to electrically connect the first partial electrode ELT1a to the second pixel electrode ELT2 of the second pixel PXL2. The second partial electrode ELT1b and the third partial electrode ELT1c may be formed using at least one of conductive ink or a chemical vapor deposition (CVD) method.

In another example, a second partial electrode ELT1′b and a third partial electrode ELT1′c may be electrodes constituting the first pixel electrode (for example, the first pixel electrode ELT1′ of FIG. 5B). In an example, in a process of disposing the pixel electrode during a manufacturing process of the display device, the first pixel electrode ELT1′ may be disposed to overlap the first dummy electrode ALE1a and the first light emitting element LD1 in the first emission area EMA1 and may be disposed to overlap the first and second dummy electrodes ALE1a and ALE2a and the first dummy electrode ALE1b in the non-emission area NEA.

In an embodiment, in case that the first pixel electrode ELT1′ of the first pixel PXL1 is disposed during the manufacturing process of the display device, since the repair electrodes (for example, the second partial electrode ELT1′b and the third partial electrode ELT1′c) are formed in advance before the repair process for the first pixel PXL1, a step of forming the repair electrodes may be omitted in the repair process for the first pixel PXL1. For example, after the first pixel electrode ELT1′ is separated into the first partial electrode ELT1′a and the isolated electrode ILT, a process of forming a contact hole in a region of the third partial electrode ELT1′c may be performed.

During the manufacturing process of the display device, by disposing the first pixel electrode ELT1′ for the repair process for a pixel in a defective state, the efficiency of the repair process for a defective pixel may be improved.

In an embodiment, the third partial electrode ELT1c and ELT1′c may be electrically connected to the first dummy electrode ALE1b of the second pixel PXL2 through a third contact hole CH3. As a result, the first partial electrode ELT1a of the first pixel PXL1 may be electrically connected to the first pixel electrode ELT1 of the second pixel PLX2.

In an embodiment, the second pixel electrode ELT2 of the second pixel PXL2 may be electrically connected to the first dummy electrode ALE1a of the second pixel PXL2 through a fourth contact hole CH4. Although the fourth contact hole CH4 is shown as being formed in the emission EMA2 of the second pixel PXL2, the disclosure is not limited thereto, and the fourth contact hole CH4 may be formed in the non-emission area NEA. In case that the fourth contact hole CH4 is formed in the non-emission area NEA, the second pixel electrode ELT2 of the second pixel PXL2 may extend from the emission area EMA2 to the non-emission area NEA.

In an embodiment, the third partial electrode ELT1c and ELT1′c may be electrically connected to the anode electrode of the second pixel PXL2 through the first dummy electrode ALE1a of the second pixel PXL2 and the second pixel electrode ELT2 of the second pixel PXL2.

In the first and second pixels PXL1 and PXL2 emitting light of a same color, in case that the light emitting elements LD of the first pixel PXL1 do not emit light due to a defect in the pixel circuit, the first pixel PXL1 in a defective state may be repaired by electrically connecting the anode electrode of the second pixel PXL2, which is adjacent thereto and in a normal state, to the first pixel PXL1. Through the repair process for the defective pixel, a decrease in light emitting efficiency of the pixel due to a defective in the pixel circuit can be prevented.

FIG. 10 is a cross-sectional view schematically illustrating an example of a cross section taken along line I-I′ of FIG. 8.

Referring to FIG. 10, the bank BNK and the first dummy electrode ALE1a of the first pixel PXL1 may be disposed on the pixel circuit layer PCL.

In an embodiment, the pixel circuit layer PCL may refer to a layer in which the pixel circuit (for example, the pixel circuit PXC of FIG. 4) including transistors and signal lines electrically connected to the transistors is disposed.

In an embodiment, the first dummy electrode ALE1a of the second pixel PXL2 may be disposed on the pixel circuit layer PCL to cover the bank BNK. The first and third insulating layers INS1 and INS3 may be disposed on the first dummy electrode ALE1a of the first pixel PXL1 and the first dummy electrode ALE1b of the second pixel PLX2. The first dummy electrode ALE1a of the second pixel PXL2 and the first and third insulating layers INS1 and INS3 may be disposed to protrude in the third direction DR3 according to the shape of the bank BNK.

In an embodiment, in the first floating area FLA1, at least portions of the first alignment electrode (for example, the first alignment electrode ALE1 of FIG. 8) and the first and third insulating layers INS1 and INS3 may be removed. The first dummy electrode ALE1a of the first pixel PXL1 and the first dummy electrode ALE1b of the second pixel PLX2 may not be electrically connected to each other.

In an embodiment, the first pixel electrode ELT1 of the first pixel PXL1 and the second pixel electrode ELT2 of the second pixel PXL2 may be disposed on the third insulating layer INS3.

In an embodiment, in the non-emission area NEA, at least one region of the first pixel electrode ELT1 of the first pixel PXL1 and a region of the third insulating layer INS3 corresponding to the cutting area LCA may be removed. The first pixel electrode ELT1 of the first pixel PXL1 may be separated into the first partial electrode ELT1a and the isolated electrode ILT. The first partial electrode ELT1a may be in a floating state. The isolated electrode ILT may be electrically connected to the first dummy electrode ALE1a electrically connected through the first contact hole CH1 and the pixel circuit of the first pixel PXL1 disposed in the pixel circuit layer PCL.

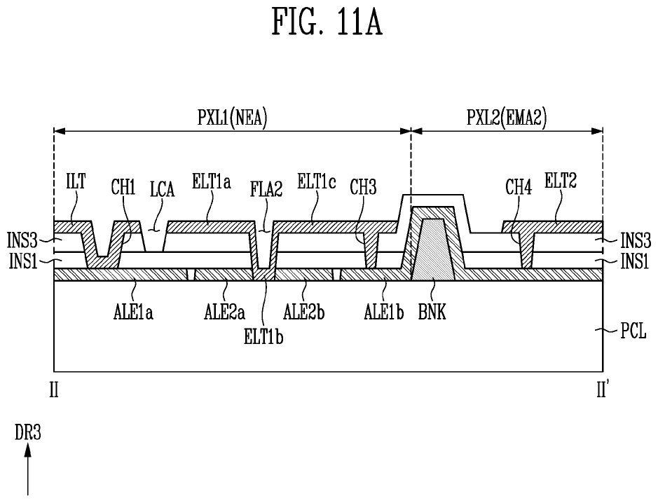

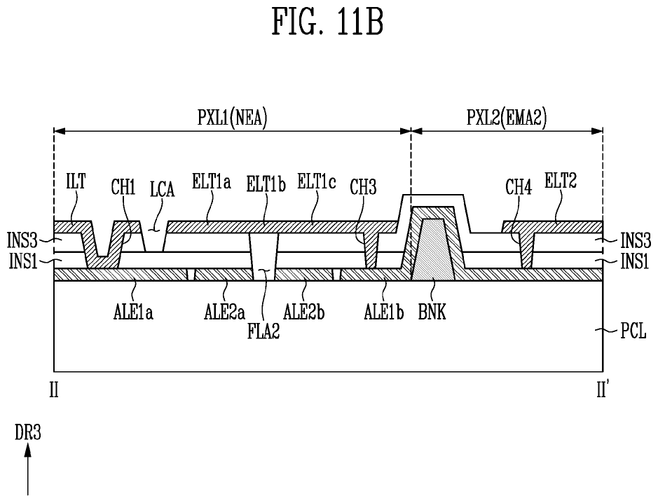

FIGS. 11A and 11B are cross-sectional views schematically illustrating an example of a cross section taken along line II-IP of FIG. 9.

Referring to FIGS. 11A and 11B, the first partial electrode ELT1a of the first pixel PXL1 may be electrically connected to the first dummy electrode ALE1a of the second pixel PXL2 through the third contact hole CH3 formed in the third partial electrode ELT1c. The second pixel electrode ELT2 of the second pixel PXL2 may be electrically connected to the first dummy electrode ALE1a of the second pixel PXL2 through the fourth contact hole CH4. For example, the first partial electrode ELT1a of the first pixel PXL1 may be electrically connected to the second pixel electrode ELT2 of the second pixels PXL2 through the third contact hole CH3.

Referring to FIG. 11A, the second partial electrode ELT1b may be disposed according to the shape of the second floating area FLA2. For example, the second partial electrode ELT1b may contact the second dummy electrode ALE2a of the first pixel PXL1 and the second dummy electrode ALE2b of the second pixel PLX2.

Referring to FIG. 11B, an insulating material (not shown) may be filled in the second floating area FLA2. For example, the second partial electrode ELT1b may be disposed on the insulating material disposed in the second floating area FLA2.

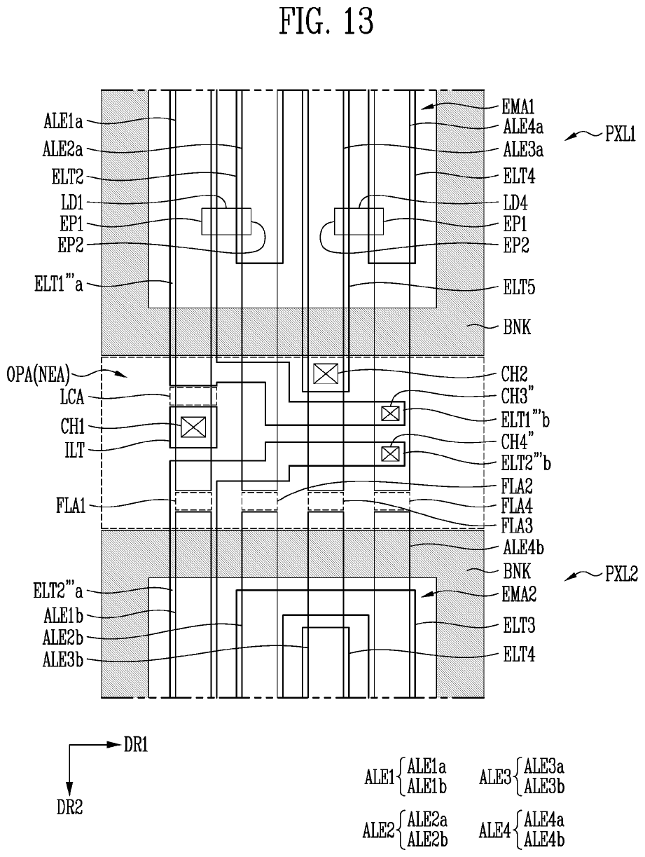

FIGS. 12 and 13 are schematic plan views illustrating other examples of the pixel for explaining the repair method for the pixel in a defective state of FIG. 7A.

Referring to FIG. 12, at least the first pixel electrode of the first pixel PXL1, the second pixel electrode of the second pixel PXL2, and third and fourth contact holes CH3′ and CH4′ may be distinguishable from those shown in FIG. 11. Therefore, the same reference numerals are used for the same or corresponding components, and duplicate descriptions will be omitted.

FIG. 12 illustrates a process of electrically connecting a first partial electrode ELT1″a to the second pixel electrode ELT2 of the second pixel PXL2 adjacent thereto after the process for disconnecting the connection between the first pixel electrode ELT1 and ELT1″ of the first pixel PXL1 and the pixel circuit PXC is performed.

Referring to FIG. 12, the first pixel electrode (for example, the first pixel electrode ELT1 and ELT1″ of FIGS. 5A and 5C) may include the first partial electrode ELT1″a. The first partial electrode ELT1″a may be integral with an electrode having a protrusion extending from the first emission area EMA1 to the non-emitting area NEA and overlapping the second dummy electrode ALE2a of the first pixel PXL1. In an example, the electrode having the protrusion may include the second partial electrode ELT1″b that protrudes from the first partial electrode ELT1″a in the first direction DR1 and overlaps a region of the second dummy electrode ALE2a.

In an embodiment, the first pixel electrode (for example, the first pixel electrode ELT1 of FIG. 5A) may be separated into the first partial electrode ELT1″a and the isolated electrode ILT. After the first pixel electrode ELT1 is separated into the first partial electrode ELT1″a and the isolated electrode ILT, the second partial electrode ELT1″b may be integral with the first partial electrode ELT1″a. For example, a process of forming the second partial electrode ELT1″b may be performed so that the first partial electrode ELT1″a is electrically connected to the second partial electrode ELT1″b.

In an embodiment, the second partial electrode ELT1″b may be a repair electrode formed to electrically connect the first partial electrode ELT1″a to the second pixel electrode ELT2 of the second pixel PXL2. The second partial electrode ELT1″b may be formed using at least one of conductive ink or a chemical vapor deposition (CVD) method.

In another embodiment, the first portion of the first pixel electrode (for example, the first pixel electrode ELT1″ of FIG. 5C) may be separated into the first partial electrode ELT1″a and the isolated electrode ILT. In an example, the second partial electrode ELT1″b may be an electrode constituting the first pixel electrode ELT1″ and may correspond to the second portion of the first pixel electrode ELT1″. In an example, the first pixel electrode ELT1″ may be disposed in the process of disposing the pixel electrode during the manufacturing process of the display device. The first pixel electrode ELT1″ may be disposed to overlap the first dummy electrode ALE1a and the first light emitting element LD1 in the first emission area EMA1, and may be disposed to overlap at least one region of the first dummy electrode ALE1a and at least one region of the second dummy electrode ALE1b in the non-emission area NEA.

In an embodiment, in case that the first pixel electrode ELT1″ of the first pixel PXL1 is disposed during the manufacturing process of the display device, since the repair electrode (for example, the second partial electrode ELT1″b) is formed in advance before the repair process for the first pixel PXL1, a step of forming the repair electrode may be omitted in the repair process for the first pixel PXL1. For example, after the first pixel electrode ELT1″ is separated into the first partial electrode ELT1″a and the isolated electrode ILT, a process of forming a contact hole in a region of the second partial electrode ELT1″b may be performed.

During the manufacturing process of the display device, by disposing the first pixel electrode ELT1″ for the repair process for a pixel in a defective state, the efficiency of the repair process for a defective pixel may be improved.

In an embodiment, the second pixel electrode (for example, the second pixel electrode ELT2″ of FIG. 5C) of the second pixel PXL2 may include a bar shape having a constant width and a shape protruding in a direction from the bar shape. In an example, the second pixel electrode ELT2″ may include a third partial electrode ELT2″a extending from the second emission area EMA2 to the non-emitting area NEA and disposed on the first dummy electrode ALE1b and a fourth partial electrode ELT2″b extending from the first portion and overlapping at least one region of the second dummy electrode ALE2a of the first pixel PXL1.

In an embodiment, the second partial electrode ELT1″b and the fourth partial electrode ELT2″b may be disposed to overlap the second dummy electrode ALE2a. The second partial electrode ELT1″b may be disposed to be spaced apart from the fourth partial electrode ELT2″b in the second direction DR2.

In an embodiment, the second partial electrode ELT1″b may be electrically connected to the second dummy electrode ALE2a through the third contact hole CH3′.

In an embodiment, the fourth partial electrode ELT2″b may be electrically connected to the second dummy electrode ALE2a through the fourth contact hole CH4′.

In an embodiment, the second partial electrode ELT1″b may be electrically connected to the anode electrode of the second pixel PXL2 through the second dummy electrode ALE2a of the first pixel PXL1 and the second pixel electrode ELT2″ of the second pixel PXL2.

Referring to FIG. 13, at least the first pixel electrode of the first pixel PXL1, the second pixel electrode of the second pixel PXL2, and third and fourth contact holes CH3″ and CH4″ may be distinguishable from those shown in FIG. 12. Therefore, the same reference numerals are used for the same or corresponding components, and duplicate descriptions will be omitted.

FIG. 13 illustrates a process of electrically connecting a first partial electrode ELT1′″a to the second pixel electrode ELT2 of the second pixel PXL2 adjacent thereto after the process for disconnecting the connection between the first pixel electrode ELT1 of the first pixel PXL1 and the pixel circuit PXC is performed.

Referring to FIG. 13, the first pixel electrode (for example, the first pixel electrode ELT1 of FIG. 5A) may include the first partial electrode ELT1′″a. The first partial electrode ELT1′″a may be integral with an electrode having a protrusion extending from the first emission area EMA1 to the non-emission area NEA and overlapping the second to fourth dummy electrodes ALE2a, ALE3a, and ALE4a of the first pixel PXL1. In an example, the electrode having the protrusion may include a second partial electrode ELT2′″b that protrudes from the first partial electrode ELT1′″a in the first direction DR1 and overlaps regions of the second to fourth dummy electrodes ALE2a, ALE3a, and ALE4a.

In an embodiment, the first pixel electrode (for example, the first pixel electrode ELT1 of FIG. 5A) may be separated into the first partial electrode ELT1′″a and the isolated electrode ILT. After the first pixel electrode ELT1 is separated into the first partial electrode ELT1′″a and the isolated electrode ILT, a second partial electrode ELT1′″b may be integral with the first partial electrode ELT1′″a. For example, a process of forming the second partial electrode ELT1′″b may be performed so that the first partial electrode ELT1′″a is electrically connected to the second partial electrode ELT1′″b.

In another example, in the process of disposing the pixel electrode during the manufacturing process of the display device, the first pixel electrode including the first partial electrode ELT1′″a and the second partial electrode ELT1′″b may be disposed. The first pixel electrode including the first partial electrode ELT1′″a and the second partial electrode ELT1′″b may be disposed to overlap the first dummy electrode ALE1a and the first light emitting element LD1 in the first emission area EMA1, and may be disposed to overlap at least regions of the first to fourth dummy electrodes ALE1a, ALE2a, ALE3a, and ALE4a in the non-emission area NEA.

In an embodiment, in case that the first pixel electrode including the first partial electrode ELT1′″a and the second partial electrode ELT1′″b is disposed during the manufacturing process of the display device, since a repair electrode (for example, the second partial electrode ELT1′″b) is formed in advance before the repair process for the first pixel PXL1, a step of forming the repair electrode may be omitted in the repair process for the first pixel PXL1. For example, after the first pixel electrode is separated into the first partial electrode ELT1′″a and the isolated electrode ILT, a process of forming a contact hole in a region of the second partial electrode ELT1′″b may be performed.

During the manufacturing process of the display device, by disposing the first pixel electrode including the first partial electrode ELTra and the second partial electrode ELT1′″b for the repair process for a pixel in a defective state, the efficiency of the repair process for a defective pixel may be improved.

In an embodiment, the second pixel electrode of the second pixel PXL2 may include a first partial electrode ELT2′″a and a second partial electrode ELT2′″b. The first partial electrode ELT2′″a may extend from the second emission area EMA2 to the non-emission area NEA and may be disposed on the first dummy electrode ALE1b. The second partial electrode ELT2′″b may extend form the first partial electrode ELT2′″a in the first direction DR1 and may overlap at least regions of the second to fourth dummy electrodes ALE2a, ALE3a, and ALE4a of the first pixel PXL1.

In an embodiment, the second partial electrode ELT1′″b and the second partial electrode ELT2′″b may be disposed to overlap at least regions of the second to fourth dummy electrodes ALE2a, ALE3a, and ALE4a. The second partial electrode ELT1′″b may be disposed to be spaced apart from the second partial electrode ELT2′″b in the second direction DR2.

In an embodiment, the second partial electrode ELT1′″b may include the third contact hole CH3″. The second partial electrode ELT1′″b may be electrically connected to the fourth dummy electrode ALE4a through the third contact hole CH3″.

In an embodiment, the second partial electrode ELT2′″b may include the fourth contact hole CH4″. The second partial electrode ELT2′″b may be electrically connected to the fourth dummy electrode ALE4a through the fourth contact hole CH4″.

In an embodiment, the second partial electrode ELT1′″b may be electrically connected to the anode electrode of the second pixel PXL2 through the fourth dummy electrode ALE4a of the first pixel PXL1 and the second pixel electrode including the first partial electrode ELT2′″a and the second partial electrode ELT2′″b of the second pixel PXL2. For a pixel including a pixel circuit in a defective state, a pixel in a defective state may be repaired by electrically connecting electrodes of a pixel in a defective state and a pixel adjacent thereto and in a normal state to the pixel in a defective state using a dummy electrode. For example, by repairing a pixel in a defective state, it can be prevented that the light emitting element of the pixel does not emit light due to a defect in the pixel circuit and thus that light emitting efficiency of the pixel is lowered.

The efficiency of the repair process for the defective pixel may be improved by pre-arranging the pixel electrode for the repair process for a pixel in a defective state in the manufacturing process of the display device.

In the display device according to the embodiments of the disclosure, an electrode of a defective pixel including a pixel circuit in a defective state may be electrically connected to an electrode of a pixel in a normal state through a dummy electrode. Through this, the defective pixel may emit light, and the decrease in light emitting efficiency due to the defective pixel not emitting light can be prevented.

The efficiency of the repair process for the defective pixel may be improved by pre-arranging the pixel electrode including a region for the repair process for the defective pixel.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first pixel including a first emission area;
a second pixel including a second emission area spaced apart from the first emission area in a second direction; and
a bank defining a non-emission area between the first emission area and the second emission area, wherein
each of the first pixel and the second pixel includes:
at least one dummy electrode spaced apart from each other in a first direction intersecting the second direction and extending in the second direction;
light emitting elements disposed between the at least one dummy electrode in an emission area;
a first pixel electrode electrically connected to a first driving power source and first ends of the light emitting elements; and
a second pixel electrode electrically connected to a second driving power source and second ends of the light emitting elements,
the first pixel electrode of the first pixel extends from the first emission area to the non-emission area,
the first pixel electrode of the first pixel is electrically connected to one of the at least one dummy electrode of the first pixel,
the first pixel electrode of the second pixel is electrically connected to the first driving power source, and
the first pixel electrode of the second pixel is electrically connected to the at least one dummy electrode.

2. The display device of claim 1, wherein the first pixel electrode of the first pixel is electrically connected to the first driving power source through the first pixel electrode of the second pixel and the at least one dummy electrode.

3. The display device of claim 1, wherein
the at least one dummy electrode of the second pixel is spaced apart from the at least one dummy electrode of the first pixel in the second direction in the non-emission area, and
the at least one dummy electrode of the second pixel is not electrically connected to the at least one dummy electrode of the first pixel.

4. The display device of claim 1, wherein
the second pixel electrode of the second pixel extends from the second emission area to the non-emission area, and
the second pixel electrode of the second pixel is electrically connected to the at least one dummy electrode through a second contact hole.

5. The display device of claim 1, wherein the at least one dummy electrode of the first pixel further includes:
a first dummy electrode overlapping the first pixel electrode of the first pixel in a plan view; and
a third dummy electrode spaced apart from the first dummy electrode in the first direction and overlapping the second pixel electrode of the first pixel in a plan view.

6. The display device of claim 5, wherein the at least one dummy electrode is disposed between the first dummy electrode and the third dummy electrode in a plan view.

7. The display device of claim 5, wherein the at least one dummy electrode is farther spaced apart from the third dummy electrode than the first dummy electrode in a plan view.

8. The display device of claim 5, wherein
the first pixel electrode of the first pixel includes:
a first partial electrode overlapping the first dummy electrode in a plan view; and
a second partial electrode protruding from the first partial electrode in the first direction and overlapping at least a portion of the at least one dummy electrode in a plan view, and
the second partial electrode is electrically connected to the at least one dummy electrode through a first contact hole.

9. The display device of claim 5, further comprising:
an isolated electrode spaced apart from the first pixel electrode of the first pixel in the second direction in the non-emission area,
wherein the isolated electrode is electrically connected to the first dummy electrode through a third contact hole.

10. A display device comprising:
a first pixel including a first emission area;
a second pixel including a second emission area spaced apart from the first emission area in a second direction; and
a bank defining a non-emission area between the first emission area and the second emission area, wherein
each of the first pixel and the second pixel includes:
at least one dummy electrode spaced apart from each other in a first direction intersecting the second direction and extending in the second direction;
light emitting elements disposed between the at least one dummy electrode in an emission area;
a first pixel electrode electrically connected to a first driving power source and first ends of the light emitting elements; and
a second pixel electrode electrically connected to a second driving power source and second ends of the light emitting elements,
the first pixel electrode of the first pixel extends from the first emission area to the non-emission area,
the first pixel electrode of the first pixel is electrically connected to one of the at least one dummy electrode of the second pixel, and
the first pixel electrode of the second pixel is electrically connected to the first driving power source, and
the first pixel electrode of the second pixel is electrically connected to the at least one dummy electrode.

11. The display device of claim 10, wherein
the at least one dummy electrode of the second pixel is spaced apart from the at least one dummy electrode of the first pixel in the second direction in the non-emission area, and
the at least one dummy electrode of the second pixel is not electrically connected to the at least one dummy electrode of the first pixel.

12. The display device of claim 11, wherein
the at least one dummy electrode of the second pixel includes a first dummy electrode, a second dummy electrode, a third dummy electrode, and a fourth dummy electrode sequentially disposed in the first direction, and
the at least one dummy electrode is the first dummy electrode.

13. The display device of claim 11, wherein the at least one dummy electrode of the first pixel includes a first dummy electrode, a second dummy electrode, a third dummy electrode, and a fourth dummy electrode sequentially disposed in the first direction, and includes an isolated electrode overlapping the first dummy electrode in the non-emission area in a plan view and at least partially surrounded by the first pixel electrode of the first pixel.

14. The display device of claim 13, wherein the first pixel electrode of the first pixel includes:
a first portion overlapping the first dummy electrode in a plan view; and
a bent portion extending from the first portion and overlapping at least a portion of the at least one dummy electrode in a plan view.

15. The display device of claim 14, wherein the bent portion includes:
a second partial electrode protruding from the first portion in the second direction and overlapping the second dummy electrode in a plan view; and
a third partial electrode overlapping at least a portion of the at least one dummy electrode which is one of second dummy electrodes, in a plan view.

16. The display device of claim 15, wherein the third partial electrode is electrically connected to the at least one dummy electrode through a first contact hole.

17. A method of manufacturing a display device, the method comprising:
disposing a pixel circuit layer on a substrate;
forming first to fourth alignment electrodes spaced apart from each other in a first direction on the pixel circuit layer;
forming a bank defining a first emission area of a first pixel, a second emission area of a second pixel disposed spaced apart from the first emission area in a second direction intersecting the first direction, and a non-emission area between the first emission area and the second emission area on the first to fourth alignment electrodes;
providing light emitting elements to each of the first emission area and the second emission area;
disposing a first pixel electrode electrically connected to one end of the light emitting elements and a second pixel electrode electrically connected to another end of the light emitting elements;
electrically separating the first to fourth alignment electrodes into at least one dummy electrode overlapping the first emission area in a plan view and at least one dummy electrode overlapping the second emission area in a plan view by removing portions of each of the first to fourth alignment electrodes in the non-emission area;
inspecting whether the first pixel and the second pixel are defective by using a mother substrate inspection device;
separating an electrical connection between the first pixel electrode of the first pixel and the pixel circuit layer in case that the first pixel is in a defective state based on an inspection result;
electrically connecting the first pixel electrode disposed in the non-emission area and one of the at least one dummy electrode of the first pixel; and
electrically connecting the at least one dummy electrode to the first pixel electrode of the second pixel.

18. The method of claim 17, wherein in the separating of the electrical connection between the first pixel electrode of the first pixel and the pixel circuit layer, the first pixel electrode is separated into an isolated electrode electrically connected to the pixel circuit layer and a partial electrode space apart from the isolated electrode and extending from the first emission area to the non-emission area by radiating a laser to the first pixel electrode in the non-emission area to remove a portion of the first pixel electrode of the first pixel.

19. The method of claim 18, wherein
a portion of the partial electrode protruding in the first direction is electrically connected to the at least one dummy electrode through a first contact hole, and
a portion of the first pixel electrode of the second pixel extending from the second emission area to the non-emission area is electrically connected to the at least one dummy electrode through a second contact hole.

20. The method of claim 19, wherein the disposing of the first pixel electrode of the first pixel and the second pixel includes:
forming the portion of the partial electrode and the portion of the first pixel electrode of the second pixel by using at least one of conductive ink and chemical vapor deposition (CVD).
